(19) United States
(12) Patent Application Publication
(10) Pub. No.: US 2026/0271601 A1
(43) Pub. Date: Sep. 10, 2026

(54) DISPLAY DEVICE AND ELECTRONIC DEVICE INCLUDING THE SAME

(71) Applicant: Samsung Display Co., LTD., Yongin-si (KR)

(72) Inventors: Yoon Sun CHOI, Yongin-si (KR); Kang San KIM, Yongin-si (KR); Jin Hwan KIM, Yongin-si (KR); Sung Joo PARK, Yongin-si (KR); Jin Koo CHUNG, Yongin-si (KR); Won Suk CHOI, Yongin-si (KR)

(21) Appl. No.: 19/429,045

(22) Filed: Dec. 22, 2025

(30) Foreign Application Priority Data
Mar. 4, 2025 (KR) 10-2025-0027444
Apr. 16, 2025 (KR) 10-2025-0049606
Nov. 10, 2025 (KR) 10-2025-0168273

(51) Int. Cl. H10K 59/80

(52) U.S. Cl. CPC H10K 59/8792; H10K 59/873

(57) ABSTRACT

Provided a display device which comprises a substrate comprising a display area in which emission areas are arranged and a non-display area located around the display area; an element layer comprising light emitting elements arranged in the emission areas on the substrate; an encapsulation layer covering the element layer; a light path control layer located on the encapsulation layer; a first dam portion located in the non-display area and surrounding a periphery of the display area; and a second dam portion located in the non-display area and surrounding a periphery of the first dam portion. The non-display area comprises a valley area located between the first dam portion and the second dam portion; and a smoothing area located around the second dam portion. A width of the smoothing area is greater than a width of the valley area.

### CROSS-REFERENCE TO RELATED APPLICATIONS

This application claims priority to Korean Patent Application No. 10-2025-0027444, filed on Mar. 4, 2025, Korean Patent Application No. 10-2025-0049606, filed on Apr. 16, 2025, and Korean Patent Application No. 10-2025-0168273, filed on Nov. 10, 2025, and all the benefits accruing therefrom under 35 U.S.C. §119, the contents of which in their entirety are herein incorporated by reference.

### BACKGROUND

### 1. Field

The present disclosure relates to a display device and an electronic device including the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer including an organic light emitting material. As described herein, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area in which an image is displayed, and a non-display area around the display area. Emission areas emitting light with respective luminances and colors may be arranged in the display area.

### SUMMARY

Electronic devices including a display device may include vehicle electronic devices such as a center information display (CID) installed on a dashboard of a vehicle.

Since the vehicle electronic device may be equipped to selectively provide information and/or content to a driver and/or a passenger depending on the driving situation of the vehicle, the display device embedded in the vehicle electronic device may include a light path control layer for controlling a viewing angle.

The light path control layer may include a plurality of organic insulating layers.

Each of the plurality of organic insulating layers may be prepared by a process of dropping and diffusing a liquid organic insulating material.

It is difficult that a process of arranging the plurality of organic insulating layers includes a process of selectively removing the diffused organic insulating material in order to prevent damage to a circuit layer, an element layer, and an encapsulation layer located under the light path control layer. Thus, the monitoring of the arrangement state of the plurality of organic insulating layers may be desired.

In view of the foregoing, aspects of the present disclosure provide a display device capable of relatively easily inspecting the arrangement state of the plurality of organic insulating layers provided in the light path control layer, and an electronic device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device which includes a substrate including a display area in which emission areas are arranged and a non-display area located around the display area; an element layer including light emitting elements arranged in the emission areas on the substrate; an encapsulation layer covering the element layer; a light path control layer located on the encapsulation layer; a first dam portion located in the non-display area and surrounding a periphery of the display area; and a second dam portion located in the non-display area and surrounding a periphery of the first dam portion. The non-display area includes a valley area located between the first dam portion and the second dam portion; and a smoothing area located around the second dam portion. A width of the smoothing area is greater than a width of the valley area.

The light path control layer includes two or more light output control layers overlapping the display area in a thickness direction of the substrate; and at least one inspection mark located in the non-display area and adjacent to at least a portion of an edge of the substrate. Each of the two or more light output control layers includes light blocking portions overlapping the display area and spaced apart from each other; a sub-insulating layer covering the light blocking portions; and a main insulating layer located on the sub-insulating layer and including an organic insulating material. The at least one inspection mark comprises two or more mark groups spaced apart from each other. Each of the two or more mark groups includes at least one valley mark located in the valley area; and one or more main marks located in the smoothing area. Each of the at least one valley mark and the one or more main marks includes engraved portions spaced apart from each other. Each of the engraved portions is formed concavely in the sub-insulating layer of each of the two or more light output control layers.

Each of the two or more light output control layers further comprises a sub-insulating layer located between the light blocking portions and the main insulating layer. Each of the sub-insulating layer and the main insulating layer extends to the non-display area. The two or more mark groups are located in the sub-insulating layers of the two or more light output control layers.

The light path control layer further comprises non-display light blocking portions overlapping the non-display area and located in the same layer as the light blocking portions of each of the two or more light output control layers. The main insulating layers of the two or more light output control layers and the non-display light blocking portions extend to the non-display area.

The edge of the substrate includes two first sides facing each other in a first direction, two second sides facing each other in a second direction, and corners where one of the two first sides and one of the two second sides meet. One of the at least one inspection mark is located adjacent to a portion of one of the two first sides or a portion of one of the two second sides.

The edge of the substrate includes two first sides facing each other in a first direction, two second sides facing each other in a second direction, and corners where one of the two first sides and one of the two second sides meet. One of the at least one inspection mark is located adjacent to at least a portion of one of the corners.

The at least one inspection mark is located in a frame shape surrounding the periphery of the display area.

The light path control layer includes two or more light output control layers overlapping the display area in a thickness direction of the substrate. The two or more light output control layers include a first light output control layer located on the encapsulation layer; a second light output control layer located on the first light output control layer; and a third light output control layer located on the second light output control layer. The first light output control layer includes first light blocking portions overlapping the display area and spaced apart from each other; a first sub-insulating layer covering the first light blocking portions of the display area; and a first main insulating layer located on the first sub-insulating layer. The second light output control layer includes second light blocking portions respectively overlapping the first light blocking portions and spaced apart from each other; a second sub-insulating layer covering the second light blocking portions; and a second main insulating layer located on the second sub-insulating layer. The third light output control layer includes third light blocking portions respectively overlapping the first light blocking portions and the second light blocking portions and spaced apart from each other; a third sub-insulating layer covering the third light blocking portions; and a third main insulating layer located on the third sub-insulating layer. The first sub-insulating layer covers the first dam portion and the second dam portion of the non-display area and extends to the smoothing area. In the smoothing area, a thickness of the first main insulating layer is gradually reduced toward an edge of the substrate.

The light path control layer further includes at least one inspection mark located in the non-display area and adjacent to at least a portion of the edge of the substrate. The at least one inspection mark includes a first mark group located in the first sub-insulating layer; a second mark group located in the second sub-insulating layer; and a third mark group located in the third sub-insulating layer. In a direction parallel to a portion of the edge of the substrate, the first mark group, the second mark group, and the third mark group are spaced apart from each other. The first mark group includes at least one first valley mark located in the valley area, and one or more first main marks located in the smoothing area. The second mark group includes at least one second valley mark located in the valley area, and one or more second main marks located in the smoothing area. The third mark group includes at least one third valley mark located in the valley area, and one or more third main marks located in the smoothing area. The engraved portions of each of the at least one first valley mark and the one or more first main marks are formed concavely in the first sub-insulating layer. The engraved portions of each of the at least one second valley mark and the one or more second main marks are formed concavely in the second sub-insulating layer. The engraved portions of each of the at least one third valley mark and the one or more third main marks are formed concavely in the third sub-insulating layer.

The light path control layer further includes one or more first auxiliary dam layers arranged between the first sub-insulating layer and the edge of the substrate and located in the same layer as the first sub-insulating layer; one or more second auxiliary dam layers arranged between the second sub-insulating layer and the edge of the substrate and located in the same layer as the second sub-insulating layer; and one or more third auxiliary dam layers arranged in the same layer as the third sub-insulating layer and the second sub-insulating layer and located in the same layer as the third sub-insulating layer. The at least one inspection mark further includes one or more first auxiliary marks located in the one or more first auxiliary dam layers; one or more second auxiliary marks located in the one or more second auxiliary dam layers; and one or more third auxiliary marks located in the one or more third auxiliary dam layers. The one or more first auxiliary marks, the one or more second auxiliary marks and the one or more third auxiliary marks are spaced apart from each other. Each of the one or more first auxiliary marks, the one or more second auxiliary marks and the one or more third auxiliary marks includes the engraved portions spaced apart from each other.

The light path control layer further includes one or more first auxiliary dam layers arranged between the first sub-insulating layer and the edge of the substrate and located in the same layer as the first sub-insulating layer; one or more second auxiliary dam layers arranged between the second sub-insulating layer and the edge of the substrate and located in the same layer as the second sub-insulating layer; and one or more third auxiliary dam layers arranged in the same layer as the third sub-insulating layer and the second sub-insulating layer and located in the same layer as the third sub-insulating layer. The one or more first auxiliary dam layers are located on the encapsulation layer.

The second sub-insulating layer covers at least one of the one or more first auxiliary dam layers. The one or more second auxiliary dam layers are located on the encapsulation layer. The third sub-insulating layer and the one or more third auxiliary dam layers are located on the second main insulating layer.

The second sub-insulating layer and the one or more second auxiliary dam layers are located on the first main insulating layer. The third sub-insulating layer and the one or more third auxiliary dam layers are located on the second main insulating layer.

The light path control layer comprises a first cladding layer located on the encapsulation layer; a first light output control layer located on the first cladding layer; a second light output control layer located on the first light output control layer; and a third light output control layer located on the second light output control layer. The first light output control layer comprises first light blocking portions overlapping the display area and spaced apart from each other; a first sub-insulating layer covering the first light blocking portions of the display area; and a first main insulating layer located on the first sub-insulating layer. The second light output control layer comprises second light blocking portions respectively overlapping the first light blocking portions and spaced apart from each other; a second sub-insulating layer covering the second light blocking portions; and a second main insulating layer located on the second sub-insulating layer. The third light output control layer comprises third light blocking portions respectively overlapping the first light blocking portions and the second light blocking portions and spaced apart from each other; a second cladding layer covering the third light blocking portions; a lens layer located on the second cladding layer; and a third main insulating layer covering the lens layer.

The light path control layer further comprises a first non-display light blocking portion overlapping the non-display area and formed in the same layer as the first light blocking portions; a second non-display light blocking portion overlapping the non-display area and formed in the same layer as the second light blocking portions; and a third non-display light blocking portion overlapping the non-display area and formed in the same layer as the third light blocking portions. The first main insulating layer extends to the non-display area and is in contact with the first non-display light blocking portion in the smoothing area. The second main insulating layer extends to the non-display area and is in contact with the second non-display light blocking portion in the smoothing area. The third main insulating layer extends to the non-display area and overlaps the third non-display light blocking portion.

According to an aspect of the present disclosure, there is provided an electronic device includes a display device displaying an image; a memory storing an application; a processor executing the application and transmitting an image data signal and an input control signal to the display device; and a power module transmitting power to the display device. The display device includes a substrate including a display area in which emission areas are arranged and a non-display area located around the display area; an element layer including light emitting elements arranged in the emission areas on the substrate; an encapsulation layer covering the element layer; a light path control layer located on the encapsulation layer; a first dam portion located in the non-display area and surrounding a periphery of the display area; and a second dam portion located in the non-display area and surrounding a periphery of the first dam portion. The light path control layer includes two or more light output control layers overlapping the display area in a thickness direction of the substrate. The non-display area includes a valley area located between the first dam portion and the second dam portion; and a smoothing area located around the second dam portion. A width of the smoothing area is greater than a width of the valley area.

The two or more light output control layers include a first light output control layer located on the encapsulation layer; a second light output control layer located on the first light output control layer; and a third light output control layer located on the second light output control layer. The first light output control layer includes first light blocking portions overlapping the display area and spaced apart from each other; a first sub-insulating layer covering the first light blocking portions of the display area; and a first main insulating layer located on the first sub-insulating layer. The second light output control layer includes second light blocking portions overlapping the first light blocking portions; a second sub-insulating layer covering the second light blocking portions; and a second main insulating layer located on the second sub-insulating layer. The third light output control layer includes third light blocking portions overlapping the first light blocking portions and the second light blocking portions; a third sub-insulating layer covering the third light blocking portions; and a third main insulating layer located on the third sub-insulating layer. The first sub-insulating layer covers the first dam portion and the second dam portion of the non-display area and extends to the smoothing area. In the smoothing area, a thickness of the first main insulating layer is gradually reduced toward an edge of the substrate.

The light path control layer further includes at least one inspection mark located in the non-display area and adjacent to at least a portion of the edge of the substrate. The at least one inspection mark includes a first mark group located in the first sub-insulating layer; a second mark group located in the second sub-insulating layer; and a third mark group located in the third sub-insulating layer. In a direction parallel to a portion of the edge of the substrate, the first mark group, the second mark group, and the third mark group are spaced apart from each other. The first mark group includes at least one first valley mark located in the valley area between the first dam portion and the second dam portion, and one or more first main marks located in the smoothing area. The second mark group includes at least one second valley mark located in the valley area, and one or more second main marks located in the smoothing area. The third mark group includes at least one third valley mark located in the valley area, and one or more third main marks located in the smoothing area. Engraved portions of each of the at least one first valley mark and the one or more first main marks are formed concavely in the first sub-insulating layer. Engraved portions of each of the at least one second valley mark and the one or more second main marks are formed concavely in the second sub-insulating layer. Engraved portions of each of the at least one third valley mark and the one or more third main marks are formed concavely in the third sub-insulating layer.

The light path control layer comprises a first cladding layer located on the encapsulation layer; a first light output control layer located on the first cladding layer; a second light output control layer located on the first light output control layer; and a third light output control layer located on the second light output control layer. The first light output control layer comprises first light blocking portions overlapping the display area and spaced apart from each other; a first sub-insulating layer covering the first light blocking portions of the display area; and a first main insulating layer located on the first sub-insulating layer. The second light output control layer comprises second light blocking portions respectively overlapping the first light blocking portions and spaced apart from each other; a second sub-insulating layer covering the second light blocking portions; and a second main insulating layer located on the second sub-insulating layer. The third light output control layer comprises third light blocking portions respectively overlapping the first light blocking portions and the second light blocking portions and spaced apart from each other; a second cladding layer covering the third light blocking portions; a lens layer located on the second cladding layer; and a third main insulating layer covering the lens layer.

The light path control layer further comprises a first non-display light blocking portion overlapping the non-display area and formed in the same layer as the first light blocking portions; a second non-display light blocking portion overlapping the non-display area and formed in the same layer as the second light blocking portions; and a third non-display light blocking portion overlapping the non-display area and formed in the same layer as the third light blocking portions. The first main insulating layer extends to the non-display area and is in contact with the first non-display light blocking portion in the smoothing area. The second main insulating layer extends to the non-display area and is in contact with the second non-display light blocking portion in the smoothing area. The third main insulating layer extends to the non-display area and overlaps the third non-display light blocking portion.

A display device according to an embodiment may include an element layer located on a substrate, an encapsulation layer covering the element layer, a light path control layer located on the encapsulation layer, and a first dam portion and a second dam portion located in a non-display area of the substrate.

The substrate may include a display area in which emission areas are arranged, and a non-display area located around the display area.

The element layer may include light emitting elements located in the emission areas on the substrate.

The non-display area may include a valley area located between the first dam portion and the second dam portion, and a smoothing area located around the second dam portion.

The light path control layer may include two or more light output control layers overlapping the display area in the thickness direction of the substrate, and at least one inspection mark located in the non-display area and adjacent to at least a portion of the edge of the substrate.

Each of two or more light output control layers may include light blocking portions overlapping the display area and spaced apart from each other, a sub-insulating layer covering the light blocking portions and including an inorganic insulating material, and a main insulating layer located on the sub-insulating layer and including an organic insulating material.

At least one inspection mark may include two or more mark groups formed in the sub-insulating layer of each of two or more light output control layers.

Each of two or more mark groups may include at least one valley mark located in the valley area, and one or more main marks located in the smoothing area.

At least one valley mark and one or more main marks may each include engraved portions spaced apart from each other.

In this way, in the process of arranging the main insulating layer, the engraved portions of the main mark interfere with the diffusion of the liquid organic insulating material, such that the edge of the main insulating layer may include a curvature due to the main mark.

Therefore, the visibility of the edges of the main insulating layers of two or more light output control layers may be improved by at least one inspection mark.

In some aspects, according to an embodiment, the diffusion of the liquid organic insulating material is easily stopped in the smoothing area of the non-display area, such that the edges of the main insulating layers of two or more light output control layers may be arranged without overlapping each other.

Therefore, the inspection of the arrangement state of two or more main insulating layers provided in two or more light output control layers may be easily performed, thereby improving the quality reliability of the display device and reducing the defect rate.

It should be noted that effects of the present disclosure are not limited to those described herein and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating a display device according to an embodiment;

FIG. 3 is a schematic diagram of an electronic device according to an embodiment;

FIG. 4 is a cross-sectional view taken along line A-A' of FIG. 2;

FIGS. 5 and 6 are schematic diagrams illustrating part B of FIG. 2 according to an embodiment;

FIG. 7 is a block diagram illustrating a display device according to an embodiment;

FIG. 8 is an equivalent circuit diagram illustrating the light emitting pixel driver of FIG. 7 according to an embodiment;

FIG. 9 is a cross-sectional view taken along line C-C' of FIG. 6 according to an embodiment;

FIG. 10 is a schematic diagram schematically illustrating a viewing angle of a display device according to an embodiment;

FIG. 11 is a plan view illustrating a display device according to an embodiment;

FIG. 12 is a cross-sectional view taken along line D-D' of FIG. 11 according to an embodiment;

FIGS. 13, 14, 15 and 16 are plan views illustrating part E of FIG. 11 according to an embodiment;

FIG. 17 is an enlarged view illustrating part F of FIG. 15;

FIG. 18 is a cross-sectional view taken along line G-G' of FIG. 17;

FIGS. 19, 20, 21, 22, and 23 are plan views illustrating a display device according to an embodiment;

FIGS. 24 and 25 are cross-sectional views taken along line D-D' of FIG. 11 according to an embodiment;

FIG. 26 is a cross-sectional view taken along line C-C' of FIG. 6 according to an embodiment;

FIG. 27 is a cross-sectional view taken along line D-D' of FIG. 11 according to an embodiment;

FIG. 28 is a block diagram of an electronic device according to an embodiment; and

FIG. 29 is schematic views of electronic devices according to various embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being "on" another layer or substrate, it can be directly on the other layer or substrate, or intervening layers may also be present. In contrast, when an element is referred to as being "directly on" another element, there may be no intervening elements present.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. The term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

It will be understood that, although the terms "first," "second," "third," or the like may be used herein to describe various elements, these elements should not be limited by these terms. These terms are used to distinguish one element from another element or for the convenience of description and explanation thereof. For example, when "a first element" is discussed in the description, it may be termed "a second element" or "a third element," and "a second element" and "a third element" may be termed in a similar manner without departing from the teachings herein.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

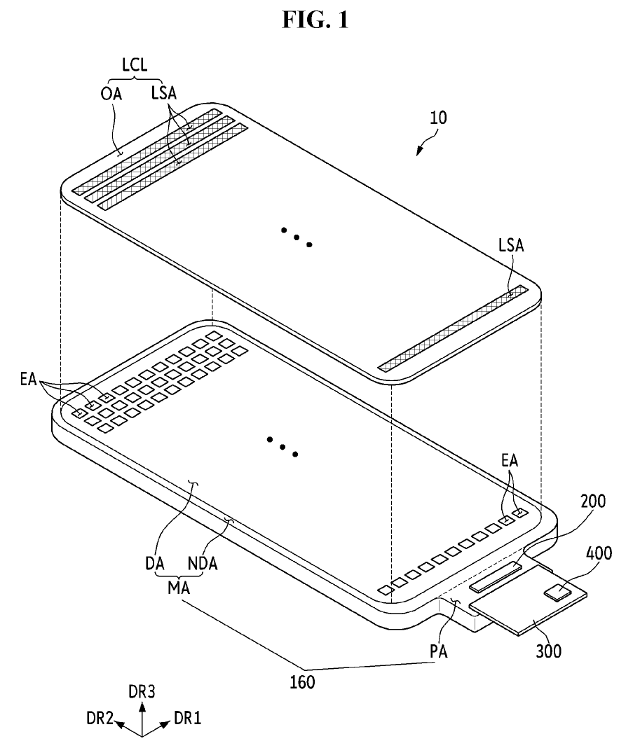

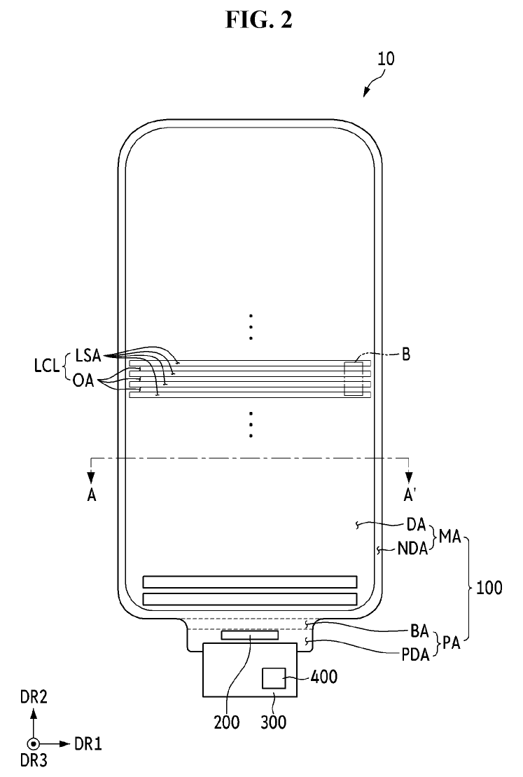

FIG. 1 is a perspective view illustrating a display device according to an embodiment. FIG. 2 is a plan view illustrating a display device according to an embodiment.

Referring to FIGS. 1 and 2, a display device 10 is a device for displaying a moving image or a still image. The display device 10 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may be any one of an organic light emitting display device, a liquid crystal display device, a plasma display device, a field emission display device, an electrophoretic display device, an electrowetting display device, a quantum dot light emitting display device, a micro LED display device, and the like. In the following description, it is assumed that the display device 10 is an organic light emitting display device, but embodiments of the present disclosure are not limited thereto.

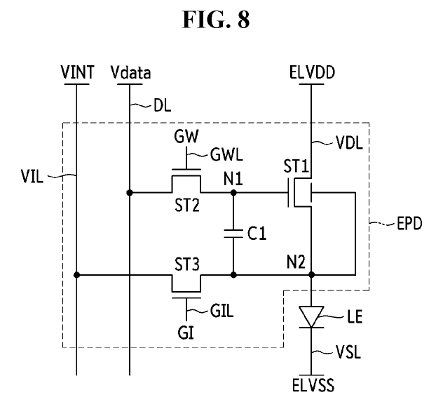

The display device 10 may include a flat panel display panel 100 that emits light for image display, a display driving circuit 200 for generating data signals Vdata (see FIG. 8) corresponding to an image signal, a circuit board 300 connected to pads of the display panel 100, and a touch driving circuit 500 for collecting a sensing signal for touch sensing.

The display panel 100 may include one surface of a quadrangle. However, this is an example, and the shape of the display panel 100 is not limited to that illustrated in FIGS. 1 and 2. That is, the display panel 100 according to an embodiment may include a surface in a polygonal shape, a circular shape, or an elliptical shape, in addition to the rectangular shape. Alternatively, at least a portion of the display panel 100 may be unfolded, and transformed to be bent, curved, folded, or rolled.

The display panel 100 may be formed to be flat, but is not limited thereto. For example, the display panel 100 may include a curved portion formed at left and right ends and having a constant curvature or a varying curvature.

In the illustrated figure, a first direction DR1 and a second direction DR2 cross each other as horizontal directions. For example, the first direction DR1 and the second direction DR2 may be orthogonal to each other. In some aspects, a third direction DR3 crosses the first direction DR1 and the second direction DR2, and may be, for example, perpendicular directions orthogonal to each other. In the present disclosure, a direction indicated by each of the first to third directions DR1, DR2, and DR3 on the drawings may be referred to as one side, and an opposite direction thereto may be referred to as the other side. Unless otherwise specified, each direction may include both sides. Unless otherwise defined, in the present specification, directions indicated by arrows of the first to third directions DR1, DR2, and DR3 may be referred to as one side, and the opposite directions thereto may be referred to as the other side. In some aspects, the terms "above," "upper side," "upper portion," "top," and "top surface," as used herein, refer to a direction indicated by an arrow in the drawing in the third direction DR3 based on the drawings, and the terms "below," "lower side," "lower portion," "bottom," and "bottom surface," as used herein, refer to a direction opposite to the direction indicated by the arrow in the third direction DR3 based on the drawings.

One surface of the display panel 100 may include a main region MA including a display area DA from which light for image display is emitted, and a non-display area NDA located around the display area DA.

The display area DA may be located in most of the main region MA.

Emission areas EA emitting light with respective luminances and colors may be arranged in the display area DA.

The non-display area NDA may not emit light for displaying an image, and may have a frame shape that surrounds the periphery of the display area DA. For example, the non-display area NDA may be maintained in a specific color such as black or the like.

The display panel 100 may include a protrusion area PA extending from a portion of the edge of the main region MA.

According to one embodiment, the protrusion area PA may protrude from the lower side of the main region MA. A length of the protrusion area PA in the first direction DR1 may be less than a length of the main region MA in the first direction DR1.

The protrusion area PA may include a bending area BA and a pad area PDA.

The bending area BA may be located between the main region MA and the pad area PDA, and may be transformed into a bent shape.

When the bending area BA is transformed into a bent shape, the pad area PDA may be located on the rear surface of the display panel 100 and may overlap the main region MA in the third direction DR3.

The display driving circuit 200 may be mounted on the pad area PDA.

In the pad area PDA, pads to which the circuit board 300 is connected may be located.

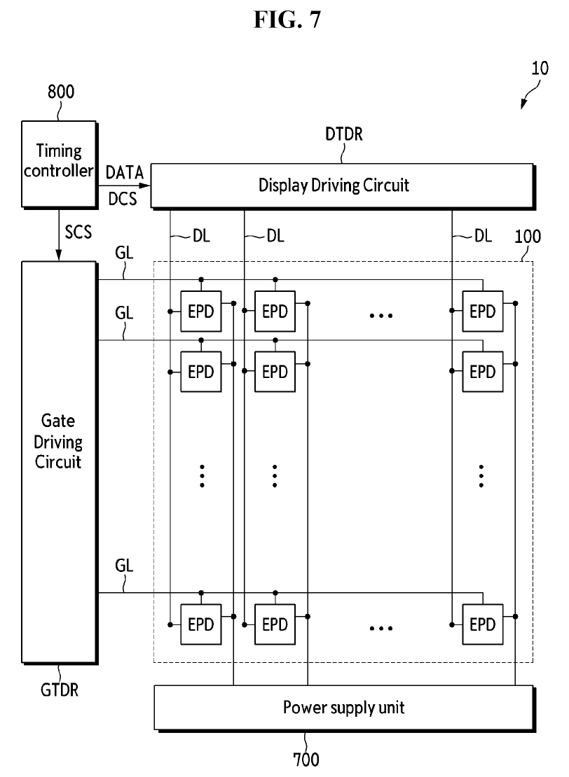

The display driving circuit 200 outputs signals and voltages for driving the display panel 100. For example, the display driving circuit 200 may supply data voltages to data lines DL (see FIGS. 7 and 8).

The display driving circuit 200 may be formed as an integrated circuit (IC) and mounted on the pad area PDA of the display panel 100 by a chip on glass (COG) method, a chip on plastic (COP) method, or an ultrasonic bonding method.

Alternatively, the display driving circuit 200 may be mounted on the circuit board 300.

The circuit board 300 may be attached onto the pads using an anisotropic conductive film. Accordingly, lead lines of the circuit board 300 may be electrically connected to the pads of the display panel 100. The circuit board 300 may be a flexible printed circuit board, a printed circuit board, or a flexible film such as a chip on film.

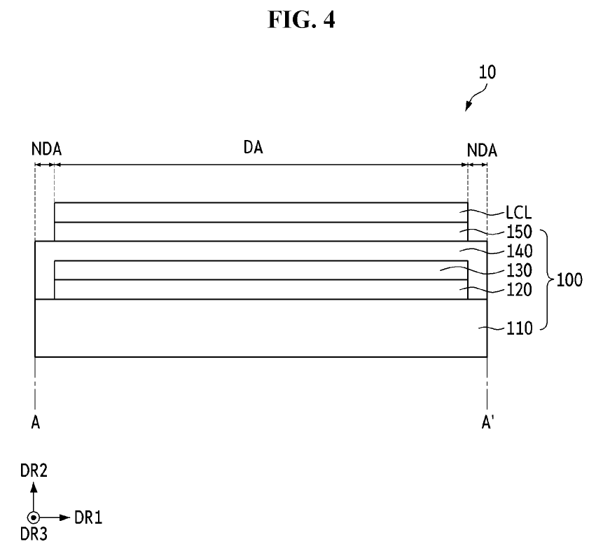

The touch driving circuit 400 may be electrically connected to a touch sensor layer 150 (see FIG. 4) of the display panel 100.

According to one embodiment, the touch driving circuit 400 may apply driving signals to the touch electrodes of the touch sensor layer 150 (see FIG. 4) and measure capacitance values of the touch electrodes. The driving signal may be a signal having a plurality of driving pulses. The touch driving circuit 400 may determine whether or not touch is inputted based on the capacitance values, and may calculate touch coordinates at which touch is inputted.

The touch driving circuit 400 may be formed as an integrated circuit (IC) and mounted on the circuit board 300.

Alternatively, the touch driving circuit 400 may be embedded in the circuit board 300.

According to one embodiment, the display device 10 may include a light path control layer LCL located on the display panel 100.

The light path control layer LCL may include non-transmission areas LSA overlapping the display area DA and spaced apart from each other, and a transmission area OA located between the non-transmission areas LSA.

Light emitted from the display panel 100 may be selectively blocked by the non-transmission areas LSA, and may be outputted to the outside through the transmission area OA.

Accordingly, the range in which light of the display panel 100 is recognized (hereinafter, referred to as "viewing angle") may be limited by the light path control layer LSL.

FIGS. 1 and 2 illustrate a case in which the non-transmission areas LSA are formed in a rectangular shape, and the transmission area OA is formed in a slit shape. However, this is an example, and the transmission area OA may have a circular shape, an elliptical shape or a polygonal shape in plan view.

The non-transmission areas LSA may extend in the first direction DR1 or the second direction DR2. For example, as illustrated in FIG. 1, the non-transmission areas LSA may extend in the first direction DR1 and may be arranged along the second direction DR2. As another example, the non-transmission areas LSA may extend in the second direction DR2 and may be arranged along the first direction DR1. As still another example, some of the non-transmission areas LSA may extend in the first direction DR1 and may be arranged along the second direction DR2, while the remainder of the non-transmission areas LSA may extend in the second direction DR2 and may be arranged along the first direction DR1.

In an embodiment, as illustrated in FIG. 1, when the non-transmission areas LSA are arranged along the second direction DR2, the viewing angle may be controlled in the second direction DR2. In another embodiment, when the non-transmission areas LSA are arranged along the first direction DR1, the viewing angle may be controlled in the first direction DR1. In the display device 10 according to this embodiment, the arrangement and shape of the transmission areas OA and the non-transmission areas LSA may be changed in various ways according to the desired or target control direction of the viewing angle.

Although it is illustrated in the drawing that the transmission area OA is located to surround the non-transmission areas LSA, embodiments of the present disclosure are not limited thereto. In some embodiments, the transmission area OA may include a plurality of transmission areas OA, and the plurality of transmission areas OA may extend in the same direction as the non-transmission areas LSA, such that the transmission areas OA and the non-transmission areas LSA may be arranged alternately with each other. For example, as illustrated in FIG. 1, when the non-transmission areas LSA extend in the first direction DR1, the plurality of transmission areas OA may extend in the first direction DR1 and may be arranged alternately with the non-transmission areas LSA in the second direction DR2.

According to one embodiment, the light path control layer LCL may be directly located on the display panel 100. In this way, the thickness of the display device 10 may be reduced, and the manufacturing process of the display device 10 may be relatively facilitated.

Alternatively, the light path control layer LCL may be provided as a film, and may be attached onto the display panel 100 by a separate adhesive layer.

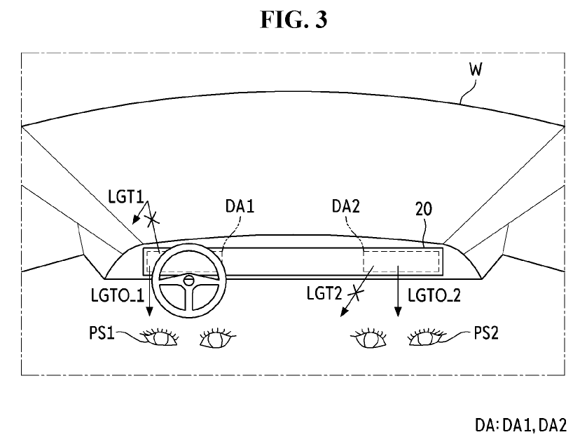

FIG. 3 is a schematic diagram of an electronic device according to an embodiment.

Referring to FIG. 3, an electronic device 20 according to an embodiment may be a device mounted on a vehicle.

The vehicle may include a body forming an exterior of the vehicle and an interior space defined by the body. The body may include a windshield W that protects a driver PS1 and a passenger PS2 from the outside and provides a view to the driver PS1. As illustrated in the drawing, the display device 10 may be provided in the interior space.

According to one embodiment, the electronic device 20 may be located on a dashboard in the interior space of the vehicle.

The electronic device 20 according to an embodiment may extend from the dashboard located in front of the driver's seat to the dashboard located in front of the passenger's seat. That is, the electronic device 10 may be an integral display continued from the dashboard located in front of the driver's seat to the dashboard located in front of the passenger's seat.

In this case, the display area DA of the electronic device 10 may include a first display area DA1 located in front of the driver's seat and a second display area DA2 located in front of the passenger’s seat.

The first display area DA1 may be located on the dashboard in front of the driver's seat and may provide vehicle operation information and navigation information to the driver PS1.

The second display area DA2 may be located on the dashboard in front of the passenger's seat and may provide entertainment information or the like to the passenger PS2.

The electronic device 20 may further include a third display area located between the first display area DA1 and the second display area DA2.

According to another embodiment, the electronic device 20 may include a first display device located on the dashboard in front of the driver's seat and a second display device located on the dashboard in front of the passenger's seat.

The driver PS1 may recognize (or visually recognize) light LGT0_1 emitted from the first display area DA1 in front of the driver's seat toward the driver PS1.

Light LGT1, which is some of the light emitted from the first display area DA1 in front of the driver's seat, may be reflected on the surrounding windshield W. In this case, the image reflected on the windshield W may interfere with the driver PS1's driving.

However, the display device 10 according to an embodiment includes the light path control layer LCL that limits the viewing angle, such that the emission direction of the light LGT0_1 emitted from the first display area DA1 in front of the driver's seat may be limited to a front direction (direction facing the driver PS1).

For example, the vertical viewing angle of the light LGT0_1 emitted from the first display area DA1 in front of the driver's seat may be limited by the light path control layer LCL, such that the light LGT1, which is some of the light emitted from the first display area DA1 in front of the driver's seat, may not be directed to the surrounding windshield W. Therefore, the convenience of the driver may be improved.

The passenger PS2 may recognize (or virtually recognize) light LGT0_2 emitted from the second display area DA2 in front of the passenger's seat toward the passenger PS2. However, light LGT2, which is some of the light emitted from the second display area DA2 in front of the passenger’s seat, may be provided toward the driver PS1. In this case, the light LGT0_2 emitted from the second display area DA2 in front of the passenger's seat interferes with the vehicle control of the driver PS1 when the vehicle is in motion, and embodiments of the present disclosure provide for restricting the driver PS1 from viewing the second display area DA2.

According to one embodiment, the display device 10 includes the light path control layer LCL, such that the emission direction of the light LGT0_2 emitted from the second display area DA2 in front of the passenger's seat may be limited to the front direction (the direction facing the passenger PS2).

For example, the horizontal viewing angles of the light LGT0_2 emitted from the second display area DA2 in front of the passenger's seat may be restricted by the light path control layer LCL, such that the light LGT0_2 emitted from the second display area DA2 in front of the passenger's seat may not be directed toward the driver. Therefore, the deterioration in the safety of the vehicle due to the electronic device 20 may be prevented.

The operation of the electronic device 20 of FIG. 3 is an example, and one embodiment is not limited to that illustrated in FIG. 3. For example, the electronic device 20 may adjust the horizontal viewing angle of the light LGT0_1 emitted from the first display area DA1 in front of the driver's seat, and may adjust the vertical viewing angle of the light LGT0_2 emitted from the second display area DA2 in front of the passenger's seat. In another example, the electronic device 20 may adjust both the vertical viewing angle and the horizontal viewing angle of each of the first display area DA1 and the second display area DA2.

According to one embodiment, when an imaginary line that faces the driver PS1 or the passenger PS2 and extends in a direction perpendicular to the display surface of the display device 10 is taken as a normal line, the viewing angle may be within 35° from the normal line. According to another embodiment, an angle within 35° from the normal line may be defined as an effective viewing angle, but embodiments of the present disclosure are not limited thereto.

FIG. 4 is a cross-sectional view taken along line A-A' of FIG. 2.

Referring to FIG. 4, the display device 10 according to an embodiment may include a substrate 110 including the display area DA and the non-display area NDA, an element layer 130 located on the substrate 110, an encapsulation layer 140 covering the element layer 130, and the light path control layer LCL located on the encapsulation layer 140.

The display device 10 according to an embodiment may further include a circuit layer 120 located on the substrate 110, and the touch sensor layer 150 located on the encapsulation layer 140. The element layer 130 may be located on the circuit layer 120, and the light path control layer LCL may be located on the encapsulation layer 140.

In other words, the display device 10 may include the display panel 100, and the light path control layer LCL located on the display panel 100.

Further, the display panel 100 may include the substrate 110 including the display area DA and the non-display area NDA, the circuit layer 120 located on the substrate 110, the element layer 130 located on the circuit layer 120, the encapsulation layer 140 covering the element layer 130, and the touch sensor layer 150 located on the encapsulation layer 140.

The emission areas EA (see FIG. 1) may be arranged in the display area DA.

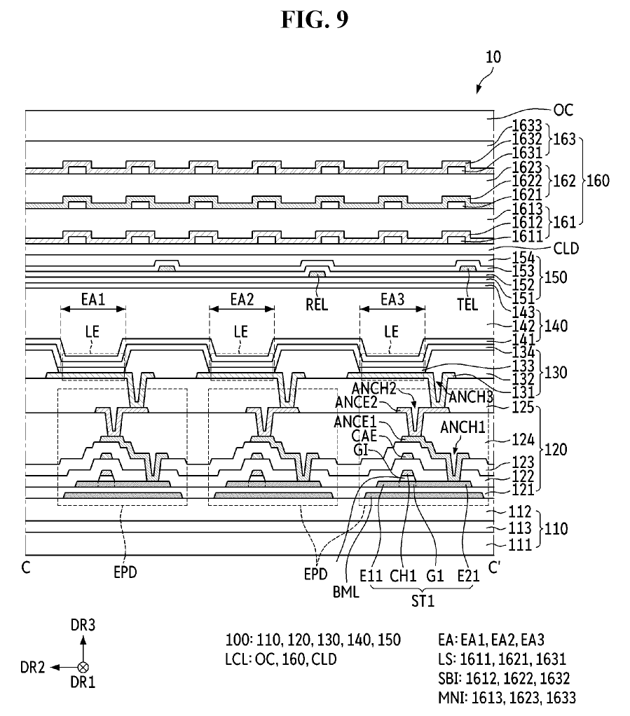

The element layer 130 may include light emitting elements LE (see FIGS. 8 and 9) located in emission areas EA (see FIG. 1) on the substrate 110.

The circuit layer 120 may include at least one semiconductor layer, two or more conductive layers, and insulating layers respectively covering them.

The encapsulation layer 140 may have a structure including two or more inorganic insulating layers and at least one organic layer interposed between the inorganic insulating layers.

Since an organic light emitting material of the light emitting elements LE of the element layer 130 may be sealed by the encapsulation layer 140, degradation of the light emitting elements LE due to oxygen or moisture may be delayed or prevented.

The touch sensor layer 150 may include touch electrodes for sensing a user's touch in a capacitive manner and the touch lines connecting the pads to the touch electrodes. For example, the touch sensor layer 150 may sense a user's touch using a self-capacitance method or a mutual capacitance method.

The touch electrodes of the touch sensor layer 150 may be located in a touch sensor area overlapping the display area DA. The touch lines of the touch sensor layer 150 may be located in a touch peripheral area overlapping the non-display area NDA.

The light path control layer LCL may overlap the display area DA.

The light path control layer LCL may transmit light emitted within a predetermined viewing angle range among the light emitted from the element layer 130 of the display panel 100, and may absorb or block the other light. Accordingly, the viewing angle of the display device 10 may be limited to a predetermined range by the light path control layer LCL.

The display device 10 according to an embodiment may further include a cover window.

The cover window may be located on the light path control layer LCL, and in this case, the light path control layer LCL and the cover window may be attached by a transparent adhesive member such as an optically clear adhesive (OCA) film.

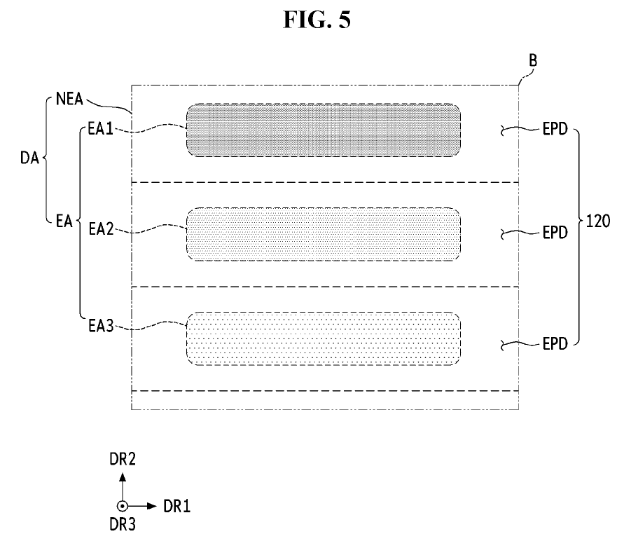

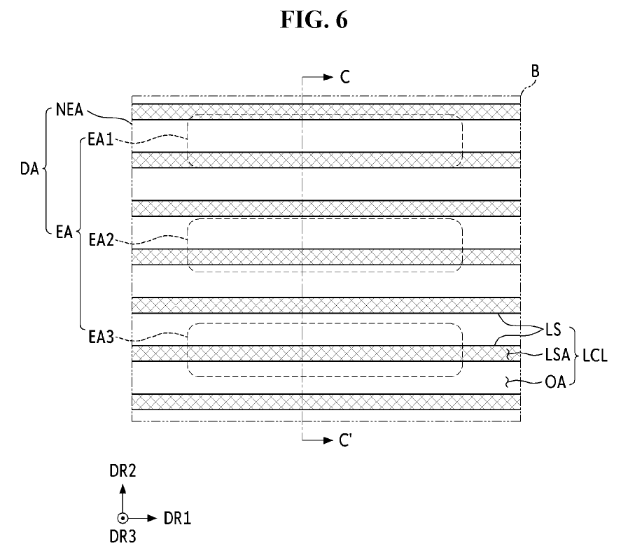

FIGS. 5 and 6 are schematic diagrams illustrating part B of FIG. 2 according to an embodiment.

As illustrated in FIG. 5, the display area DA may include the emission areas EA from which light is emitted, and a non-emission area NEA that is a separation area between the emission areas EA and from which light is not emitted.

Each of the emission areas EA may be a unit area that emits light in a wavelength band corresponding to one color of two or more different colors with a luminance corresponding to an image signal.

Each of the emission areas EA may be arranged in a quadrilateral shape.

However, this is an example, and the planar shape of the emission areas EA according to an embodiment is not limited to that illustrated in FIG. 5. That is, the emission areas EA may have, in plan view, a circular shape, an elliptical shape, or a polygonal shape such as a rectangle, a square, a hexagon, or an octagon, rather than a rhombus.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

For example, the first wavelength band may be from about 600 nm to about 750 nm and may correspond to a red color. The second wavelength band may be from about 480 nm to about 560 nm and may correspond to a green color. The third wavelength band may be from about 370 nm to about 460 nm and may correspond to a blue color.

However, this is an example, and the first wavelength band, the second wavelength band, and the third wavelength band according to an embodiment are not limited thereto.

Since the emission areas EA include the first emission area EA1, the second emission area EA2, and the third emission area EA3, each of unit pixels may be provided by a combination of one or more first emission areas EA1, one or more second emission areas EA2, and one or more third emission areas EA3 adjacent to each other among the emission areas EA.

Each of the unit pixels may be a unit for displaying various colors including white. That is, lights of various colors displayed by the unit pixels may be implemented as a mixture of lights emitted from two or more emission areas EA included in each unit pixel.

The third emission area EA3 may have a width greater than the width of the first emission area EA1, and the first emission area EA1 may have a width greater than the width of the second emission area EA2. However, this is an example, and the width of each of the emission areas EA is not limited to the examples illustrated in FIG. 5.

According to one embodiment, the circuit layer 120 may include the light emitting pixel drivers EPD arranged in the first direction DR1 and the second direction DR2 in the display area DA.

The element layer 130 (see FIG. 4) may include light emitting elements LE (see FIGS. 8 and 9) respectively located in the emission areas EA.

The light emitting pixel drivers EPD may be respectively electrically connected to the light emitting elements LE (see FIGS. 8 and 9).

As illustrated in FIG. 6, according to an embodiment, the light path control layer LCL may include the non-transmission areas LSA that overlap the display area DA, are spaced apart from each other, and block light, the transmission area OA that is located between the non-transmission areas LSA and transmits light, and light blocking portions LS that overlap the non-transmission areas LSA.

In other words, the transmission area OA may be an area that does not overlap the light blocking portions LS.

A portion of each of the emission areas EA may overlap at least one of the non-transmission areas LSA in the third direction DR3, and another part of each of the emission areas EA may overlap the transmission area OA in the third direction DR3.

FIG. 7 is a block diagram illustrating a display device according to an embodiment.

As illustrated in FIG. 7, the display device 10 according to an embodiment may include the display panel 100, the data driver DTDR supplying the data signals Vdata (see FIG. 8) to the data lines DL of the display panel 100, the gate driver GTDR supplying gate signals to gate lines GL of the display panel 100, a power supply unit 700 supplying powers and voltages to the display panel 100, and a timing controller 800 controlling the driving timing of each of the data driver DTDR and the gate driver GTDR.

The display panel 100 may include the light emitting pixel drivers EPD respectively electrically connected to the light emitting elements LE (see FIGS. 8 and 9) of the element layer 130 (see FIG. 4), the gate lines GL transmitting the gate signals to the light emitting pixel drivers EPD, and the data lines DL transmitting the data signals Vdata (see FIG. 8) to the light emitting pixel drivers EPD.

Each of the gate signals is used for controlling a turn-on/turn-off operation of at least one of two or more transistors provided in each of the light emitting pixel drivers EPD.

The data signals Vdata are used for controlling the luminance of the light emitting elements LE arranged in the emission areas EA.

The timing controller 800 receives an image signal supplied from the outside of the display device 10.

The timing controller 800 may output image data DATA and a data control signal DCS to the data driver DTDR.

The data driver DTDR may convert the image data DATA into analog data voltages according to the data control signal DCS and output the data signals Vdata to the data lines DL.

The data driver DTDR may be embedded in the display driving circuit 200 (see FIGS. 1 and 2) formed as the integrated circuit IC.

The timing controller 800 may generate a scan control signal SCS for controlling the operation timing of the gate driver GTDR.

The gate driver GTDR may generate gate signals in response to the scan control signal SCS and output the gate signals to gate lines GL.

The gate signals may have pulses that vary to a first gate level voltage or a second gate level voltage.

The power supply unit 700 may supply various power and voltages supportive of driving the light emitting pixel drivers EPD.

FIG. 8 is an equivalent circuit diagram illustrating the light emitting pixel driver of FIG. 7 according to an embodiment.

As illustrated in FIG. 8, the light emitting pixel driver EPD may be electrically connected between a first power line VDL that transmits a first power ELVDD and one end of the light emitting element LE. The other end of the light emitting element LE may be electrically connected to a second power line VSL that transmits a second power ELVSS.

The second power ELVSS may be at a voltage level lower than a voltage level of the first power ELVDD.

That is, the anode electrode of the light emitting element LE may be electrically connected to the light emitting pixel driver EPD, and the cathode electrode of the light emitting element LE may be electrically connected to a second power source ELVSS.

The light emitting element LE may be an organic light emitting diode (OLED) having an organic light emitting layer, a quantum dot light emitting diode (LED) including a quantum dot light emitting layer, a micro LED, or an inorganic LED having an inorganic semiconductor.

The light emitting pixel driver EPD may include a first transistor ST1 that generates a driving current of the light emitting element LE, and one or more capacitors C1 and one or more transistors ST2 and ST3 electrically connected to the first transistor ST1.

The first transistor ST1 may be electrically connected between the first power line VDL and the light emitting element LE.

The first electrode of the first transistor ST1 may be electrically connected to the first power line VDL.

The second electrode of the first transistor ST1 may be electrically connected to a second node N2 and the anode electrode of the light emitting element LE.

The first gate electrode of the first transistor ST1 may be electrically connected to a first node N1 and the second transistor ST2.

The second gate electrode of the first transistor ST1 may be electrically connected to the second node N2.

The second transistor ST2 may be electrically connected between the data line DL and the first node N1.

The gate electrode of the second transistor ST2 may be electrically connected to the scan write line GWL. That is, the second transistor ST2 may be turned on by the scan write signal of the scan write line GWL.

When the second transistor ST2 is turned on, the data signal Vdata of the data line DL may be transmitted to the first node N1.

Due to the data signal Vdata transmitted to the first node N1, a voltage difference between the gate electrode of the first transistor ST1 and the first electrode of the first transistor ST1, i.e., a gate-source voltage difference, becomes a difference voltage between the first power ELVDD and the data signal Vdata, and thus may become greater than the threshold voltage of the first transistor ST1. Therefore, by turning on the first transistor ST1, a source-drain current of a magnitude corresponding to the data signal Vdata may be generated between the first electrode and the second electrode of the first transistor ST1. Further, the source-drain current of the first transistor ST1 may be supplied as a driving current to the light emitting element LE.

Accordingly, the driving current of the magnitude corresponding to the data signal Vdata is supplied to the light emitting element LE and, thus, the light emitting element LE may emit light with a luminance corresponding to the data signal Vdata.

The first capacitor C1 may be electrically connected between the first node N1 and the second node N2.

The first capacitor C1 may be charged by the data signal Vdata transmitted to the first node N1 through the turned-on second transistor ST2.

Hence, the potential of the first node N1 may be maintained for a predetermined period of time due to the voltage charged in the first capacitor C1.

The third transistor ST3 may be electrically connected between the initialization voltage line VIL and the second node N2.

The gate electrode of the third transistor ST3 may be electrically connected to the scan initialization line GIL. That is, the third transistor ST3 may be turned on by the scan initialization signal GI of the scan initialization line GIL.

When the third transistor ST3 is turned on, the potential of the second node N2, i.e., the potential of the anode electrode of the light emitting element LE, may be initialized to the initialization voltage VINT of the initialization voltage line VIL.

As illustrated in FIG. 8, according to an embodiment, each of the first, second, and third transistors ST1, ST2, and ST3 may be an N-type MOSFET. However, this is an example, and at least one of the first, second, and third transistors ST1, ST2, and ST3 may be a P-type MOSFET.

The light emitting pixel driver EPD of the display device 10 according to an embodiment is not limited to that illustrated in FIG. 8.

FIG. 9 is a cross-sectional view taken along line C-C' of FIG. 6 according to an embodiment.

As illustrated in FIG. 9, the display panel 100 of the display device 10 according to an embodiment may include the substrate 110, the circuit layer 120 located on the substrate 110, the element layer 130 located on the circuit layer 120, the encapsulation layer 140 located on the element layer 130, and the touch sensor layer 150 located on the encapsulation layer 140.

The substrate 110 may include a first base layer 111 and a second base layer 112 stacked in the third direction DR3.

Each of the first base layer 111 and the second base layer 112 may be formed of an insulating material such as glass, quartz, polymer resin or the like. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate may include a metal material.

The substrate 110 may further include a substrate buffer layer 113 located between the first base layer 111 and the second base layer 112.

The substrate buffer layer 113 is used for blocking moisture or oxygen permeating through the first base layer 111 and the second base layer 112.

The substrate buffer layer 113 may include a plurality of inorganic films laminated alternately. For example, each of the inorganic films of the substrate buffer layer 113 may include one of a silicon nitride layer, a silicon oxynitride layer, a silicon oxide layer, a titanium oxide layer, and an aluminum oxide layer.

The circuit layer 120 may include a lower metal layer BML located on the substrate 110, a buffer layer 121 covering the lower metal layer BML, a semiconductor layer (including a channel portion CH1, a first electrode portion E11, and a second electrode portion E21 of the first transistor ST1) located on the buffer layer 121, a gate insulating layer GI covering the channel portion CH1 of the semiconductor layer, a first gate conductive layer (including a first gate electrode G1 of the first transistor ST1) located on the gate insulating layer GI, a first interlayer insulating layer 122 covering the semiconductor layer and the first gate conductive layer, a second gate conductive layer (including a capacitor electrode CAE) located on the first interlayer insulating layer 122, a second interlayer insulating layer 123 covering the second gate conductive layer, a first source-drain conductive layer (including a first anode connection electrode ANCE1) located on the second interlayer insulating layer 123, a first planarization layer 124 covering the first source-drain conductive layer, a second source-drain conductive layer (including a second anode connection electrode ANCE2) located on the first planarization layer 124, and a second planarization layer 125 covering the second source-drain conductive layer.

Each of the buffer layer 121, the gate insulating layer GI, the first interlayer insulating layer 122, and the second interlayer insulating layer 123 may include an inorganic insulating material such as silicon nitride, silicon oxynitride, silicon oxide, titanium oxide, or aluminum oxide.

The lower metal layer BML, the first gate conductive layer (including the first gate electrode G1 of the first transistor ST1), and the second gate conductive layer (including the capacitor electrode CAE) may each be formed as a single layer or multiple layers formed of any one of molybdenum (Mo), aluminum (Al), chromium (Cr), gold (Au), titanium (Ti), nickel (Ni), neodymium (Nd) and copper (Cu), or an alloy thereof.

The lower metal layer BML is used for preventing a leakage current from occurring in the channel portion CH1 of the first transistor ST1 due to light incident through the substrate 110. The lower metal layer BML may overlap the channel portion CH1 of the first transistor ST1 in the third direction DR3.

The semiconductor layer (including the channel portion CH1, the first electrode portion E11, and the second electrode portion E21 of the first transistor ST1) may include polycrystalline silicon, monocrystalline silicon, low-temperature polycrystalline silicon, amorphous silicon, or an oxide semiconductor.

In the semiconductor layer, the channel portion CH1 of the first transistor ST1 overlaps the gate insulating layer GI and the first gate electrode G1, and thus maintains a semiconductor property, and the other portions except the channel portion CH1 of the first transistor ST1 may have conductivity by impurity or ion doping.

That is, in the semiconductor layer, the first electrode portion E11 and the second electrode portion E21 of the first transistor ST1 may have conductivity.

The first gate electrode G1 of the first transistor ST1 located in the first gate conductive layer may overlap the channel portion CH1 of the first transistor ST1 in the third direction DR3.

The capacitor electrode CAE located in the second gate conductive layer may overlap the first gate electrode G1 of the first transistor ST1 in the third direction DR3.

The first source-drain conductive layer (including the first anode connection electrode ANCE1) and the second source-drain conductive layer (including the second anode connection electrode ANCE2) located on the first planarization layer 124 may each be formed as multiple layers including molybdenum (Mo), aluminum (Al), chromium (Cr), gold (Au), titanium (Ti), nickel (Ni), neodymium (Nd), and copper (Cu).

Each of the first planarization layer 124 and the second planarization layer 125 may include an organic insulating material such as acryl resin, epoxy resin, phenolic resin, polyamide resin, polyimide resin and the like.

The first anode connection electrode ANCE1 located in the first source-drain conductive layer may be electrically connected to the second electrode portion E21 of the first transistor ST1 through a first anode connection hole ANCH1.

The second anode connection electrode ANCE2 located in the second source-drain conductive layer may be electrically connected to the first anode connection electrode ANCE1 through a second anode connection hole ANCH2.

The element layer 130 may be located on the second planarization layer 125.

The element layer 130 may include first electrodes 131 located in the emission areas EA, a pixel defining layer 132 located in the non-emission areas NEA and covering the edges of the first electrodes 131, light emitting layers 133 located on the first electrodes 131, and a second electrode 134 located on the pixel defining layer 132 and the light emitting layers 133.

Each of the light emitting elements LE of the emission areas EA may be formed in a structure in which the light emitting layer 133 is interposed between the first electrode 131 and the second electrode 134 facing each other.

The first electrode 131 may be located on the second planarization layer 125, and may be electrically connected to the second anode connection electrode ANCE2 through a third anode connection hole ANCH3.

Accordingly, the first electrode 131 may be electrically connected to the second electrode portion E21 of the first transistor ST1 through the first anode connection electrode ANCE1 and the second anode connection electrode ANCE2.

The first electrodes 131 may be respectively located in the emission areas EA and respectively electrically connected to the light emitting pixel drivers EPD, and thus may be referred to as pixel electrodes or anode electrodes.

The second electrode 134 may be located in the entire display area DA including the emission areas EA and the non-emission area NEA and is shared by the light emitting elements LE, and thus may be referred to as a common electrode or a cathode electrode. Alternatively, the second electrode 134 may be a part of the second power line VSL (see FIG. 8).

The element layer 130 may further include a first common layer located between the first electrode 131 and the light emitting layer 133, and a second common layer located between the light emitting layer 133 and the second electrode 134.

The first common layer may include a hole transport layer. In some aspects, the first common layer may further include a hole injection layer.

The second common layer may include an electron transport layer. In some aspects, the second common layer may further include an electron injection layer.

Each of the light emitting layers 133 may include an organic light emitting material.

The pixel defining layer 132 may include an organic insulating material.

The encapsulation layer 140 may include a first encapsulation layer 141 located on the element layer 130 and including an inorganic insulating material, a second encapsulation layer 142 located on the first encapsulation layer 141 and including an organic insulating material, and a third encapsulation layer 143 covering the second encapsulation layer 142 and including an inorganic insulating material.

For example, the first encapsulation layer 141 and the third encapsulation layer 143 may each be formed as a single layer or multiple layers including at least one of silicon nitride, silicon oxynitride, silicon oxide, titanium oxide, or aluminum oxide.

The second encapsulation layer 142 may include a polymer-based organic insulating material. Polymer-based materials may include polyethylene terephthalate, polyethylene naphthalate, polycarbonate, polyimide, polyethylene sulfonate, polyoxymethylene, polyarylate, hexamethyldisiloxane, and acrylic resin (e.g., polymethyl methacrylate, polyacrylic acid, or the like), or any combination thereof.

The touch sensor layer 150 may be located on the encapsulation layer 140. The touch sensor layer 150 may include touch electrodes for detecting a signal that varies depending on the touch of a person or an object and sensing a point on the display surface where the touch of the person or the object has occurred.

The touch sensor layer 150 may include a first touch insulating layer 151 located on the encapsulation layer 140, a first touch electrode REL located on the first touch insulating layer 151, a second touch insulating layer 152 covering the first touch electrode REL, a second touch electrode TEL located on the second touch insulating layer 152, a third touch insulating layer 153 covering the second touch electrode TEL, and a touch planarization layer 154 flatly covering the third touch insulating layer 153.

Each of the first touch insulating layer 151, the second touch insulating layer 152, and the third touch insulating layer 153 may include an inorganic insulating material. However, this is an example, and at least one of the first touch insulating layer 151, the second touch insulating layer 152, or the third touch insulating layer 153 may include an organic insulating material.

The touch planarization layer 154 may include an organic insulating material such as acryl resin, epoxy resin, phenolic resin, polyamide resin, polyimide resin and the like.

According to one embodiment, the light path control layer LCL may include two or more light output control layers 160 overlapping the display area DA (see FIG. 4) in the third direction DR3.

Each of two or more light output control layers 160 may include light blocking portions LS overlapping the display area DA and spaced apart from each other, a sub-insulating layer SBI covering the light blocking portions LS, and a main insulating layer MNI located on the sub-insulating layer SBI.

According to one embodiment, the sub-insulating layer SBI may include an inorganic insulating material.

Alternatively, each of the sub-insulating layer SBI and the main insulating layer MNI may include an organic insulating material.

For example, the sub-insulating layer SBI may be formed through a process of partially etching an organic insulating material deposited by a vapor deposition method.

According to one embodiment, the main insulating layer MNI may be formed through a process of diffusing an organic insulating material dropped by an inkjet printing method.

According to one embodiment, two or more light output control layers 160 may include a first light output control layer 161 located on the encapsulation layer 140 of the display panel 100, a second light output control layer 162 located on the first light output control layer 161, and a third light output control layer 163 located on the second light output control layer 162.

The first light output control layer 161 may include first light blocking portions 1611 overlapping the display area DA and spaced apart from each other, a first sub-insulating layer 1612 covering the first light blocking portions 1611, and a first main insulating layer 1613 located on the first sub-insulating layer 1612.

The second light output control layer 162 may include second light blocking portions 1621 overlapping the first light blocking portions 1611, a second sub-insulating layer 1622 covering the second light blocking portions 1621, and a second main insulating layer 1623 located on the second sub-insulating layer 1622.

The third light output control layer 163 may include third light blocking portions 1631 overlapping the first light blocking portions 1611 and the second light blocking portions 1621, a third sub-insulating layer 1632 covering the third light blocking portions 1631, and a third main insulating layer 1633 located on the third sub-insulating layer 1632.

In other words, when two or more light output control layers 160 include the first light output control layer 161, the second light output control layer 162, and the third light output control layer 163, the light blocking portions LS of two or more light output control layers 160 may include the first light blocking portions 1611, the second light blocking portions 1621, and the third light blocking portions 1631.

Further, the sub-insulating layers SBI of two or more light output control layers 160 may include the first sub-insulating layer 1612, the second sub-insulating layer 1622, and the third sub-insulating layer 1632, and the main insulating layers MNI of two or more light output control layers 160 may include the first main insulating layer 1613, the second main insulating layer 1623, and the third main insulating layer 1633.

The light blocking portions LS may overlap the non-transmission areas LSA, and may include a material that blocks or absorbs light.

For example, each of the light blocking portions LS may be a photosensitive resin, and may include an organic black pigment such as carbon black or the like.

The sub-insulating layers SBI may include an inorganic insulating material such as silicon nitride, silicon oxynitride, silicon oxide, titanium oxide, or aluminum oxide.

The main insulating layers MNI may include at least one organic insulating material selected from the group consisting of propylene glycol methyl ether acetate, methacrylic acid-benzylmethacrylic acid copolymer, multi-functional acrylate, and a photo initiator.

As other example, each of the sub-insulating layers SBI and the main insulating layers MNI may include at least one organic insulating material of propylene glycol methyl ether acetate, methacrylic acid-benzylmethacrylic acid copolymer, multi-functional acrylate, or a photo initiator.

According to one embodiment, the light path control layer LCL may further include at least one cladding layer CLD located on the display panel 100.

One of at least one cladding layer CLD may be located between two or more light output control layers 160 and the display panel 100.

That is, two or more light output control layers 160 may be located on one cladding layer CLD.

At least one cladding layer CLD may include an inorganic insulating material.

For example, at least one cladding layer CLD may include an inorganic insulating material such as silicon nitride, silicon oxynitride, silicon oxide, titanium oxide, or aluminum oxide.

According to one embodiment, the light path control layer LCL may further include an overcoat layer OC covering two or more light output control layers 160.

The overcoat layer OC may include an organic insulating material and may be located relatively flat.

Alternatively, to improve the light efficiency of the display device 10, the overcoat layer OC may be omitted from the light path control layer LCL.

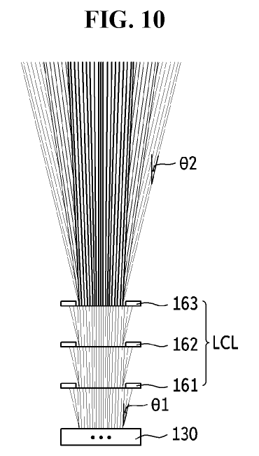

FIG. 10 is a schematic diagram schematically illustrating a viewing angle of a display device according to an embodiment.

As illustrated in FIG. 10, light generated by the element layer 130 of the display panel 100 may be emitted at an emission angle θ1 corresponding to the width of the emission area EA.

According to one embodiment, the display device 10 includes the light path control layer LCL located on the display panel 100.

The light path control layer LCL includes two or more light output control layers 161, 162, and 163 that are sequentially stacked, and each of two or more light output control layers 161, 162, and 163 includes the light blocking portions LS overlapping the non-transmission area LSA.

Accordingly, the light emitted from the element layer 130 of the display panel 100 may selectively pass through the transmission area OA between the non-transmission areas LSA, such that the viewing angle of the display device 10 may be limited to a range corresponding to the width of the transmission area OA and the gap between two or more light output control layers 161, 162, and 163.

Therefore, the viewing angle of the display device 10 may be less than the emission angle θ1.

According to one embodiment, the viewing angle of the display device 10 may be about 15 degrees or less.

According to one embodiment, the process of arranging the main insulating layers MNI may include a process of dropping a liquid organic insulating material by an inkjet printing process, and a process of widely diffusing the dropped liquid organic insulating material.

If the dropping amount of the liquid organic insulating material is excessively large, the main insulating layers MNI overlap the cutting line for individual separation of the device, such that the quality reliability of the display device 10 may deteriorate.

In some aspects, in order to prevent unnecessary damage to the display panel 100, it is difficult that the process of arranging the main insulating layers MNI includes a process of selectively removing the organic insulating material that has been diffused to a range greater than or equal to a threshold.

Therefore, embodiments of the present disclosure provide for performing a monitoring process for the arrangement state of the main insulating layers MNI.

Accordingly, each of the following embodiments provides the display device 10 in which the visibility of the edges of the main insulating layers MNI may be improved in order to relatively easily inspect the arrangement state of the main insulating layers MNI.

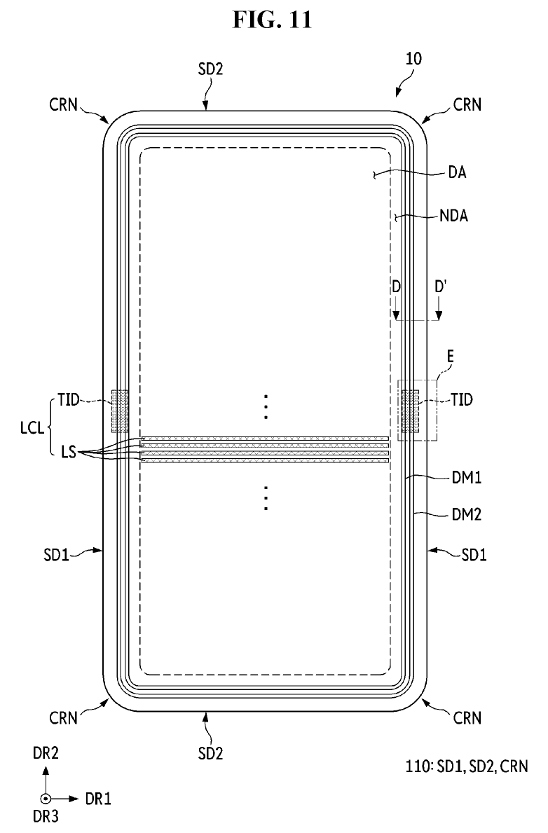

FIG. 11 is a plan view illustrating a display device according to an embodiment.

As illustrated in FIG. 11, the display device 10 according to an embodiment may include the light path control layer LCL located on the display panel 100, a first dam portion DM1 located in the non-display area NDA and surrounding the periphery of the display area DA, and a second dam portion DM2 surrounding the periphery of the first dam portion DM1.

The first dam portion DM1 and the second dam portion DM2 are used for limiting the arrangement range of the second encapsulation layer 142 (see FIG. 9) of the encapsulation layer 140 (see FIG. 9).

The light path control layer LCL may include the light blocking portions LS located in the non-transmission areas LSA.

According to one embodiment, the light path control layer LCL may include at least one inspection mark TID located in the non-display area NDA and adjacent to at least a portion of the edge of the substrate 110.

For reference, in this specification, the edge of the substrate 110 may refer to the edge of the main region MA of the substrate 110.

According to one embodiment, the edge of the substrate 110 may include two first sides SD1 facing each other in the first direction DR1, two second sides SD2 facing each other in the second direction DR2, and corners CRN where one of two first sides SD1 and one of two second sides SD2 meet.

According to one embodiment, the corners CRN may be curved.

According to one embodiment of FIG. 11, at least one inspection mark TID may be located adjacent to a portion of each of two first sides SD1.

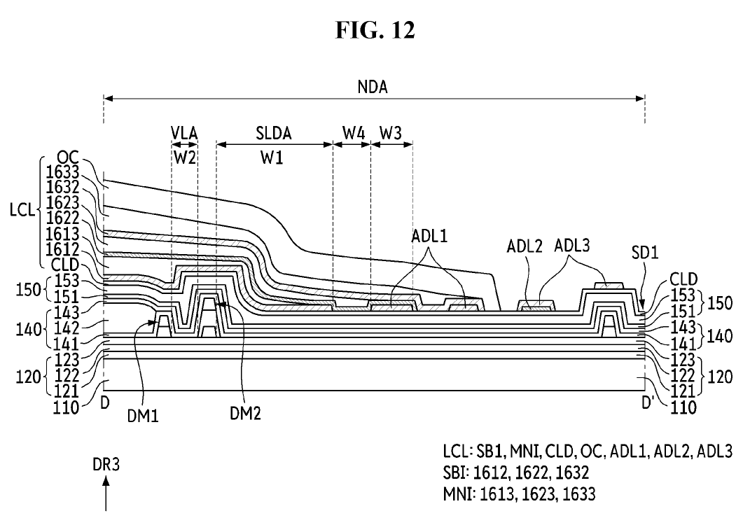

FIG. 12 is a cross-sectional view taken along line D-D' of FIG. 11 according to an embodiment.

Referring to FIG. 12, the display device 10 according to an embodiment may include the substrate 110 including the display area DA (see FIG. 11) and the non-display area NDA, the element layer 130 located on the substrate 110, the encapsulation layer 140 covering the element layer 130, the light path control layer LCL located on the encapsulation layer 140, the first dam portion DM1 located in the non-display area NDA and surrounding the periphery of the display area DA, and the second dam portion DM2 located in the non-display area NDA and surrounding the periphery of the first dam portion DM1.

According to one embodiment, the light path control layer LCL may include two or more light output control layers 160 overlapping the display area DA (see FIG. 4) in the third direction DR3.

Two or more light output control layers 160 may include the first light output control layer 161 located on the encapsulation layer 140 of the display panel 100, the second light output control layer 162 located on the first light output control layer 161, and the third light output control layer 163 located on the second light output control layer 162.

The first light output control layer 161 may include the first sub-insulating layer 1612 covering the first light blocking portions 1611 (see FIG. 9), and the first main insulating layer 1613 located on the first sub-insulating layer 1612.

The second light output control layer 162 may include the second sub-insulating layer 1622 covering the second light blocking portions 1621 (see FIG. 9), and the second main insulating layer 1623 located on the second sub-insulating layer 1622.

The third light output control layer 163 may include the third sub-insulating layer 1632 covering the third light blocking portions 1631 (see FIG. 9), and the third main insulating layer 1633 located on the third sub-insulating layer 1632.

According to one embodiment, the light path control layer LCL may further include one or more first auxiliary dam layers ADL1 arranged between the first sub-insulating layer 1612 and the edge of the substrate 110 (i.e., the first side SD1) and located in the same layer as the first sub-insulating layer 1612, one or more second auxiliary dam layers ADL2 arranged between the second sub-insulating layer 1622 and the edge of the substrate 110 (the first side SD1 of FIG. 11) and located in the same layer as the second sub-insulating layer 1622, and one or more third auxiliary dam layers ADL3 arranged between the third sub-insulating layer 1632 and the edge of the substrate 110 (the first side SD1 of FIG. 11) and located in the same layer as the third sub-insulating layer 1632.

According to one embodiment, the non-display area NDA may include a valley area VLA located between the first dam portion DM1 and the second dam portion DM2, and a smoothing area SLDA located around the second dam portion DM2.

According to one embodiment, the first sub-insulating layer 1612 may cover the first dam portion DM1 and the second dam portion DM2 of the non-display area NDA and may extend to the smoothing area SLDA.

That is, the first sub-insulating layer 1612 may overlap the valley area VLA and the smoothing area SLDA.

The thickness of the first main insulating layer 1613 on the first sub-insulating layer 1612 may be primarily reduced in the valley area VLA, and may be gradually reduced toward the edge of the substrate 110 in the smoothing area SLDA to converge to a minimum thickness.

The smoothing area SLDA may be spaced apart from the edge of the substrate 110 (i.e., the first side SD1).

For example, the smoothing area SLDA may be spaced apart from one or more first auxiliary dam layers ADL1.

According to one embodiment, a width W1 of the smoothing area SLDA may be greater than a width W2 of the valley area VLA.

For example, the width W1 of the smoothing area SLDA may be about 80 μm or more.

In this way, in the process of widely diffusing the liquid organic insulating material during the process of arranging the main insulating layers MNI, the diffusion of the organic insulating material is primarily slowed down in the valley area VLA, and may be relatively easily stopped by the flat surface of the smoothing area SLDA.

Accordingly, even if the process of arranging the main insulating layers MNI does not include the process of selectively removing the organic insulating material, the arrangement range of the main insulating layers MNI may be relatively easily limited.

Therefore, the quality reliability and defect rate of the display device 10 may be improved.

One or more first auxiliary dam layers ADL1 may serve as an auxiliary means to prevent the second main insulating layer 1623 and the third main insulating layer 1633 from being in contact with the edge of the substrate 110 (i.e., the first side SD1) by forming valleys between the first sub-insulating layer 1612 and one or more first auxiliary dam layers ADL1.

According to one embodiment, a minimum distance W4 between the smoothing area SLDA and one or more first auxiliary dam layers ADL1 may be greater than a width W3 of one first auxiliary dam layer ADL1 among the one or more first auxiliary dam layers ADL1.

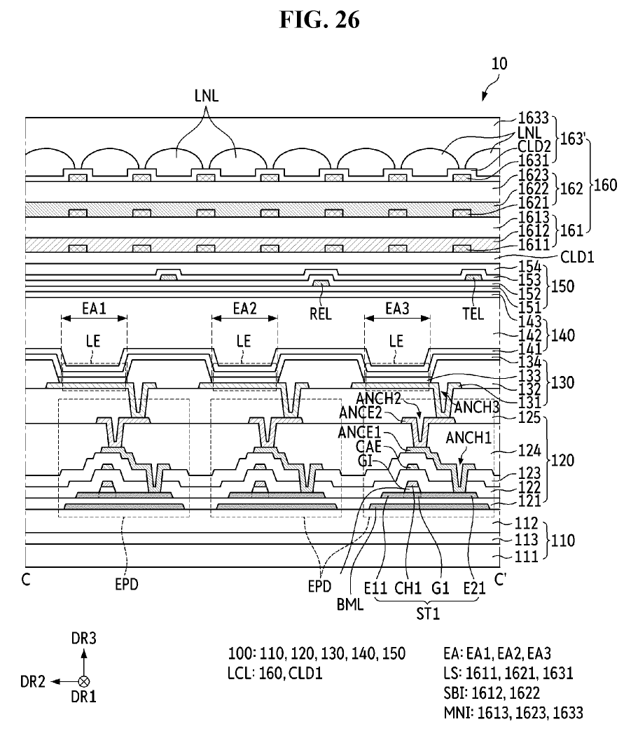

One or more second auxiliary dam layers ADL2 may serve as an auxiliary means to prevent the third main insulating layer 1633 from being in contact with the edge of the substrate 110 (the first side SD1 of FIG. 11) by forming valleys between the second sub-insulating layer 1622 and one or more second auxiliary dam layers ADL2. FIG. 26 is a cross-sectional view taken along line C-C' of FIG. 6 according to one embodiment.

One or more third auxiliary dam layers ADL3 may serve as an auxiliary means to prevent the third main insulating layer 1633 from being in contact with the edge (the first side SD1 of FIG. 11) of the substrate 110 by forming valleys between the third sub-insulating layer 1632 and one or more third auxiliary dam layers ADL3.

According to one embodiment, one or more first auxiliary dam layers ADL1 may be located on the encapsulation layer 140.

According to one embodiment, the second sub-insulating layer 1622 may cover the first main insulating layer 1613, and at least one of one or more first auxiliary dam layers ADL1.

In another example, one of one or more second auxiliary dam layers ADL2 may be located on another one of one or more first auxiliary dam layers ADL1.

According to one embodiment, the third sub-insulating layer 1632 may cover the second main insulating layer 1623.

The third sub-insulating layer 1632 may cover at least one of one or more first auxiliary dam layers ADL1, or at least one of one or more second auxiliary dam layers ADL2.

One of one or more third auxiliary dam layers ADL3 may be located on another one of one or more first auxiliary dam layers ADL1, or another one of one or more second auxiliary dam layers ADL2.

According to one embodiment, the overcoat layer OC of the light path control layer LCL may cover the third main insulating layer 1633.

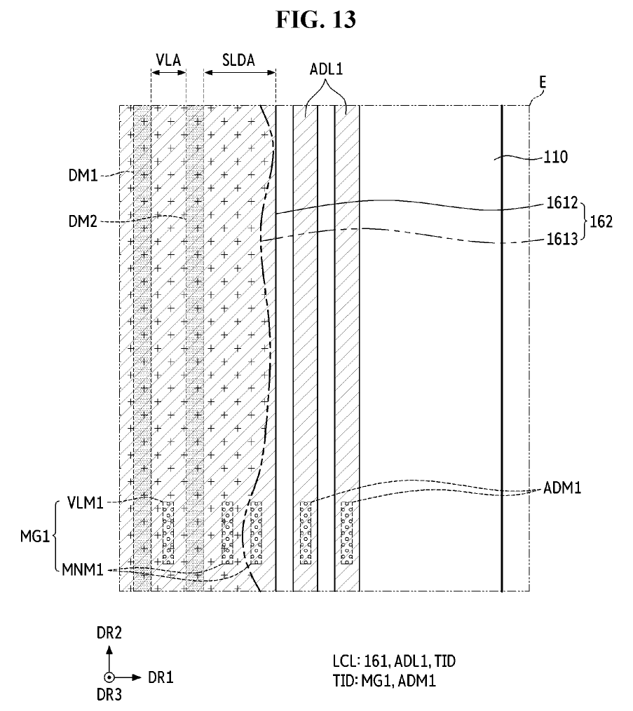

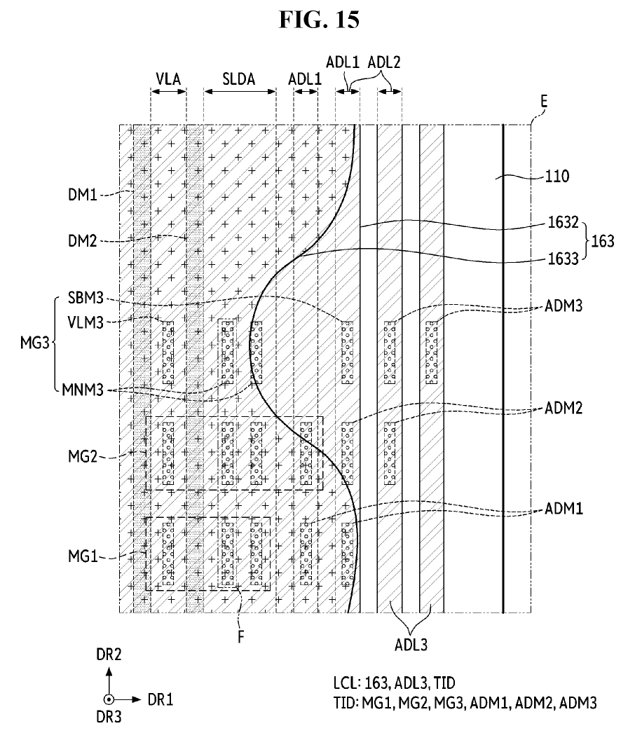

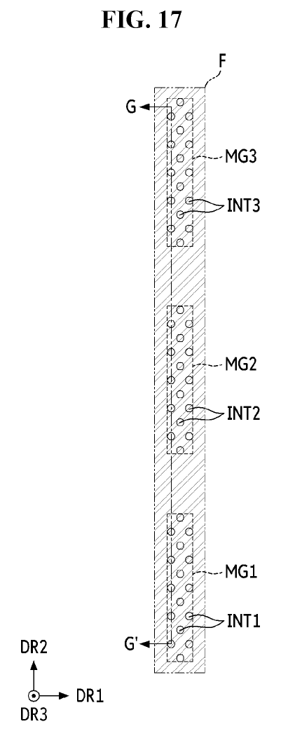

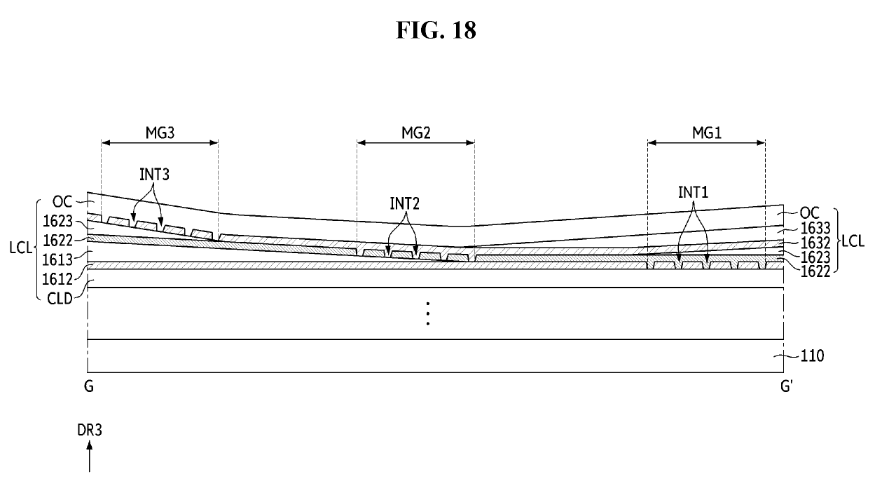

FIGS. 13, 14, 15 and 16 are plan views illustrating part E of FIG. 11 according to an embodiment. FIG. 17 is an enlarged view illustrating part F of FIG. 15. FIG. 18 is a cross-sectional view taken along line G-G' of FIG. 17.

FIG. 13 illustrates an example of the first light output control layer 161 and the inspection mark TID in part E of FIG. 11.

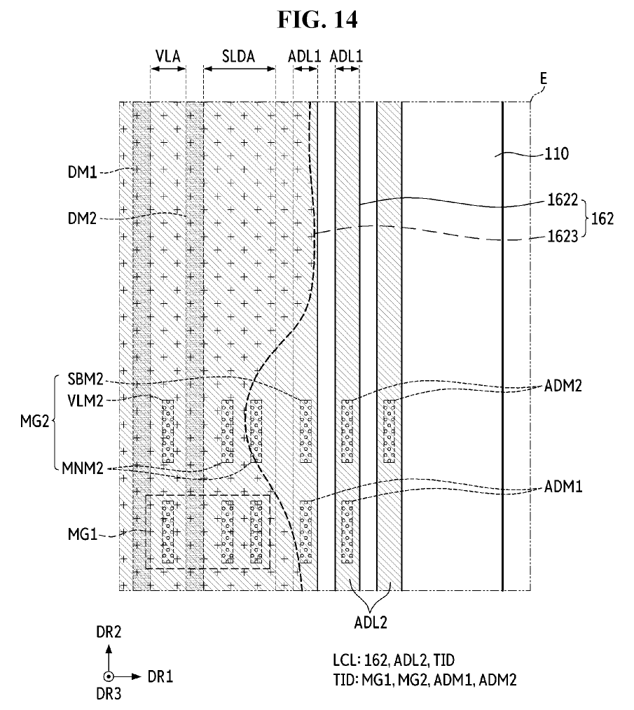

FIG. 14 illustrates an example of the second light output control layer 162 and the inspection mark TID in part E of FIG. 11.

FIG. 15 illustrates an example of the third light output control layer 163 and the inspection mark TID in part E of FIG. 11.

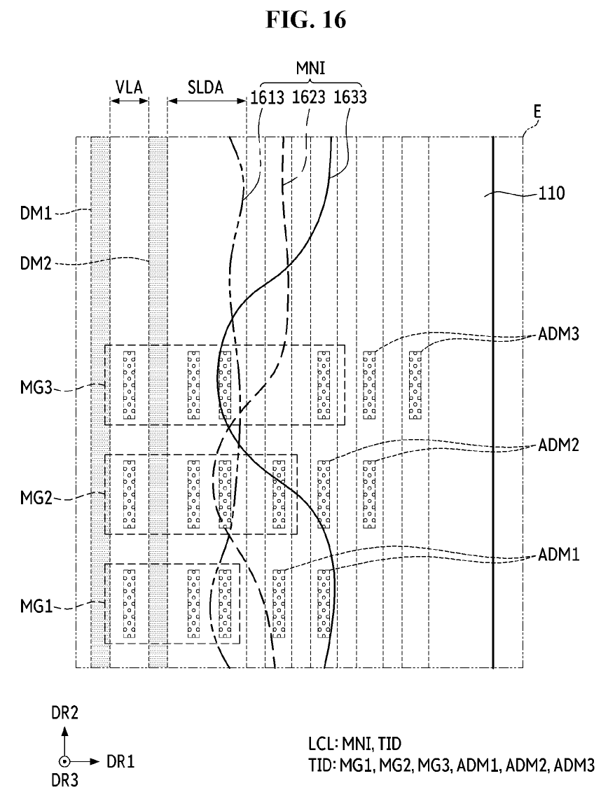

FIG. 16 illustrates an example of the edges of the main insulating layers MNI in part E of FIG. 11.

As illustrated in FIG. 11, the light path control layer LCL of the display device 10 according to an embodiment may include at least one inspection mark TID.

As illustrated in FIGS. 13, 14 and 15, at least one inspection mark TID may include two or more mark groups MG1, MG2, and MG3 located in the respective sub-insulating layers 1612, 1622, and 1623 of two or more light output control layers 161, 162, and 163 and spaced apart from each other.

Two or more mark groups MG1, MG2, and MG3 may include at least one valley mark VLMb, VLM2, and VLM3 located in the valley area VLA, and one or more main marks MNM1, MNM2, and MNM3 located in the smoothing area SLDA, respectively.

At least one valley mark VLM1, VLM2, and VLM3 and one or more main marks MNM1, MNM2, and MNMb may include engraved portions INTb, INT2, and INT3 (see FIGS. 17 and 18) spaced apart from each other, respectively.

The engraved portions INT1, INT2, and INT3 (see FIGS. 17 and 18) may be formed concavely in the sub-insulating layer 1612, 1622, and 1623, respectively.

When two or more light output control layers 160 include the first light output control layer 161, the second light output control layer 162, and the third light output control layer 163, at least one inspection mark TID may include the first mark group MG1 (see FIGS. 13, 14, and 15) located in the first sub-insulating layer 1612 of the first light output control layer 161, the second mark group MG2 (see FIGS. 14 and 15) located in the second sub-insulating layer 1622 of the second light output control layer 162, and the third mark group MG3 (see FIG. 15) located in the third sub-insulating layer 1632 of the third light output control layer 163.

As illustrated in FIG. 15, in a direction (the second direction DR2 of FIG. 15) parallel to a portion of the edge of the substrate 110, the first mark group MG1, the second mark group MGb, and the third mark group MG3 may be spaced apart from each other.

In this way, as illustrated in FIG. 16, the deformed portion caused by the first mark group MGb in the edge of the first main insulating layer 1613, the deformed portion caused by the second mark group MG2 in the edge of the second main insulating layer 1623, and the deformed portion caused by the third mark group MG3 in the edge of the third main insulating layer 1633 may be spaced apart from each other in a direction (the second direction DR2 of FIG. 15). Therefore, according to an embodiment, the identification of each of the first main insulating layer 1613, the second main insulating layer 1623, and the third main insulating layer 1633 may be facilitated by at least one inspection mark TID.

As illustrated in FIG. 13, the first mark group MG1 corresponding to the first sub-insulating layer 1612 may include at least one first valley mark VLMb located in the valley area VLA and one or more first main marks MNM1 located in the smoothing area SLDA.

At least one first valley mark VLMb and one or more first main marks MNM1 may be arranged side by side in another direction (the first direction DRb of FIG. 13) perpendicular to one direction (the second direction DR2 of FIG. 13) parallel to a portion of the edge of the substrate 110.

Since the width W1 (see FIG. 12) of the smoothing area SLDA is greater than the width W2 (see FIG. 12) of the valley area VLA, the number or gap of one or more first main marks MNM1 may be greater than the number or gap of at least one first valley mark VLM1. For example, the number of first main marks MNM1 may be greater than the number of first valley marks VLM1. Further, for example, gaps between the first main marks MNM1 may be greater than gaps between the first valley marks VLM1.

Since the surface tension of the first sub-insulating layer 1612 varies due to the first engraved portions INT1 (see FIGS. 17 and 18) of the first mark group MG1, the diffusion shape of the organic insulating material may include the deformation corresponding to the first mark group MG1 in the process of arranging the first main insulating layer 1613. Accordingly, the edge of the first main insulating layer 1613 on the first sub-insulating layer 1612 may include the deformed portion caused by the first mark group MG1.

According to one embodiment, at least one inspection mark TID may further include at least one first auxiliary mark ADM1 located in at least one first auxiliary dam layer ADL1.

At least one first auxiliary mark ADM1 may be arranged side by side with at least one first valley mark VLM1 and one or more first main marks MNM1 in another direction (the first direction DR1 of FIG. 13).

As illustrated in FIG. 14, the second mark group MG2 corresponding to the second sub-insulating layer 1622 may include at least one second valley mark VLM2 located in the valley area VLA, and one or more second main marks MNM2 located in the smoothing area SLDA.

At least one second valley mark VLM2 and one or more second main marks MNM2 may be arranged side by side in another direction (the first direction DR1 of FIG. 14).

Since the width W1 (see FIG. 12) of the smoothing area SLDA is greater than the width W2 (see FIG. 12) of the valley area VLA, the number or gap of one or more second main marks MNM2 may be greater than the number or gap of at least one second valley mark VLMb.

Since the surface tension of the second sub-insulating layer 1622 varies due to the second engraved portions INT2 (see FIGS. 17 and 18) of the second mark group MG2, the edge of the second main insulating layer 1623 on the second sub-insulating layer 1622 may include the deformed portion caused by the second mark group MG2.

According to one embodiment, the second sub-insulating layer 1622 may further cover at least one first auxiliary dam layer ADL1 adjacent to the first sub-insulating layer 1612 among one or more first auxiliary dam layers ADL1.

The second mark group MG2 may further include at least one second sub-mark SBM2 formed at a portion of the second sub-insulating layers 1622 that overlaps at least one first auxiliary dam layer ADL1.

At least one second sub-mark SBM2 may be arranged side by side with at least one second valley mark VLM2 and one or more second main marks MNM2 in another direction (the first direction DRb of FIG. 14).

According to one embodiment, at least one inspection mark TID may further include one or more second auxiliary marks ADM2 located in one or more second auxiliary dam layers ADL2.

One or more second auxiliary marks ADM2 may be arranged side by side with at least one second valley mark VLM2 and one or more second main marks MNM2 in another direction (the first direction DR1 of FIG. 14).

As illustrated in FIG. 15, the third mark group MG3 corresponding to the third sub-insulating layer 1632 may include at least one third valley mark VLM3 located in the valley area VLA, and one or more third main marks MNM3 located in the smoothing area SLDA.

At least one third valley mark VLM3 and one or more third main marks MNM3 may be arranged side by side in another direction (the third direction DR1 of FIG. 15).

Since the width W1 (see FIG. 12) of the smoothing area SLDA is greater than the width W2 (see FIG. 12) of the valley area VLA, the number or gap of one or more third main marks MNM3 may be greater than the number or gap of at least one third valley mark VLM3.

Since the surface tension of the third sub-insulating layer 1632 varies due to the third engraved portions INT3 (see FIGS. 17 and 18) of the third mark group MG3, the edge of the third main insulating layer 1633 on the third sub-insulating layer 1612 may include the deformed portion caused by the third mark group MG3.

According to one embodiment, the third sub-insulating layer 1632 may further cover at least one second auxiliary dam layer ADL2 adjacent to the second sub-insulating layer 1622 among one or more second auxiliary dam layers ADL2.

The third mark group MG3 may further include at least one third sub-mark SBM3 formed at a portion of the third sub-insulating layer 1632 that overlaps at least one second auxiliary dam layer ADL2.

At least one third sub-mark SBM3 may be arranged side by side with at least one third valley mark VLM3 and one or more third main marks MNM3 in another direction (the first direction DR1 of FIG. 14).

According to one embodiment, at least one inspection mark TID may further include one or more third auxiliary marks ADM3 located in one or more third auxiliary dam layers ADLb.

One or more third auxiliary marks ADM3 may be arranged side by side with at least one third valley mark VLM3 and one or more third main marks MNM3 in another direction (the third direction DR1 of FIG. 15).

As illustrated in FIG. 16, according to an embodiment, the edges of the main insulating layers MNI include the deformed portion caused by at least one inspection mark TID, such that the identification between the main insulating layers MNI may be facilitated.

Therefore, the inspection of the arrangement state of the main insulating layers MNI may be relatively facilitated.

As illustrated in FIGS. 17 and 18, the first engraved portions INT1 of the first mark group MG1 may be spaced apart from each other and may be formed concavely in the first sub-insulating layer 1612.

The second engraved portions INT2 of the second mark group MG2 may be spaced apart from each other and may be formed concavely in the second sub-insulating layer 1622.

The third engraved portions INT3 of the third mark group MG3 may be spaced apart from each other and may be formed concavely in the third sub-insulating layer 1632.

FIG. 17 illustrates a case where the first engraved portions INT1, the second engraved portions INT2, and the third engraved portions INT3 are arranged at a predetermined interval, but this is an example, and the arrangement shape of the first engraved portions INT1, the second engraved portions INT2, and the third engraved portions INT3 according to an embodiment is not limited to that illustrated in FIG. 17. That is, the first engraved portions INT1, the second engraved portions INT2, and the third engraved portions INT3 may be arranged at a random interval, or the interval in the first direction DR1 and the interval in the second direction DR2 may regularly vary.

Similarly to the illustration of FIG. 18, each of the engraved portions of one or more first auxiliary marks ADM1 (see FIG. 13) may be concavely formed in one or more first dam layers ADL1 (see FIG. 13).

Each of the engraved portions of one or more second auxiliary marks ADM2 (see FIG. 14) may be formed concavely in one or more second dam layers ADL2 (see FIG. 14).

Each of the engraved portions of one or more third auxiliary marks ADM3 (see FIG. 15) may be formed concavely in one or more third dam layers ADL3 (see FIG. 15).

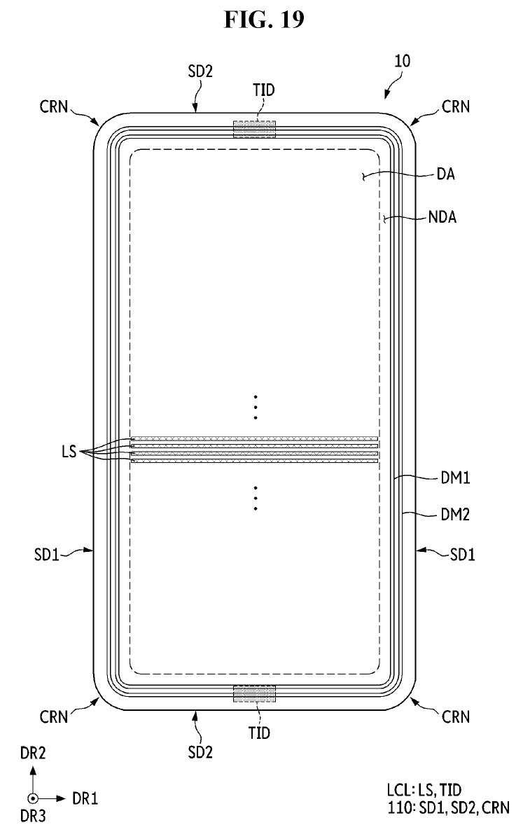

FIGS. 19, 20, 21, 22, and 23 are plan views illustrating a display device according to an embodiment.

The display device 10 according to an embodiment of FIG. 19 is substantially the same as one embodiment illustrated in FIGS. 11 to 18, except that at least one inspection mark TID is located adjacent to a portion of each of the second sides SD2 facing each other in the second direction DR2, instead of the first sides SD1, in the edge of the substrate 110, such that the redundant description will be omitted below.

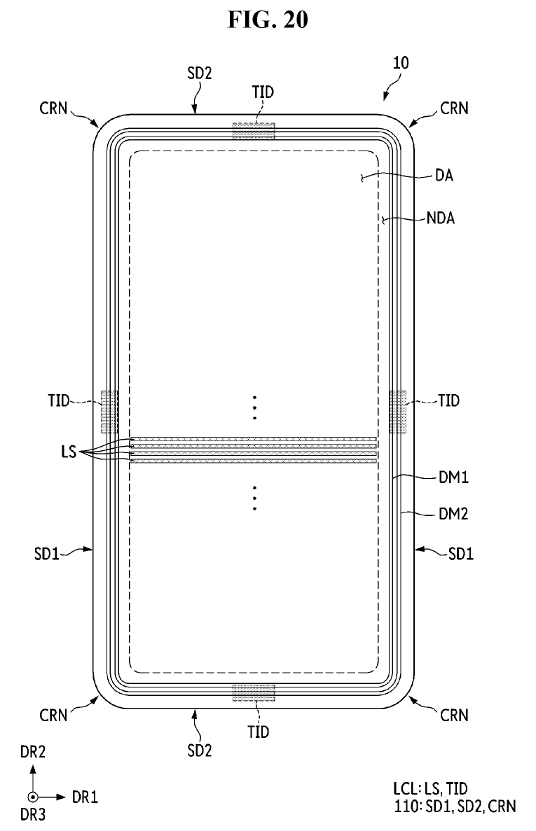

The display device 10 according to an embodiment of FIG. 20 is substantially the same as one embodiment illustrated in FIGS. 11 to 18, except that at least one inspection mark TID is located adjacent to a portion of each of the second sides SD2 as well as a portion of each of the first sides SD1 in the edge of the substrate 110, such that the redundant description will be omitted below.

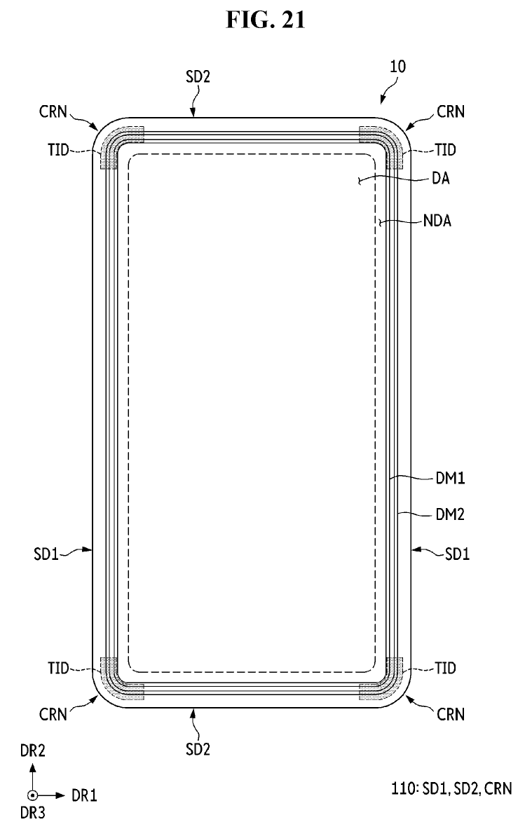

The display device 10 according to an embodiment of FIG. 21 is substantially the same as one embodiment illustrated in FIGS. 11 to 18, except that at least one inspection mark TID is located adjacent to at least a portion of each of the corners CRN, instead of the first sides SD1, in the edge of the substrate 110, such that the redundant description will be omitted below.

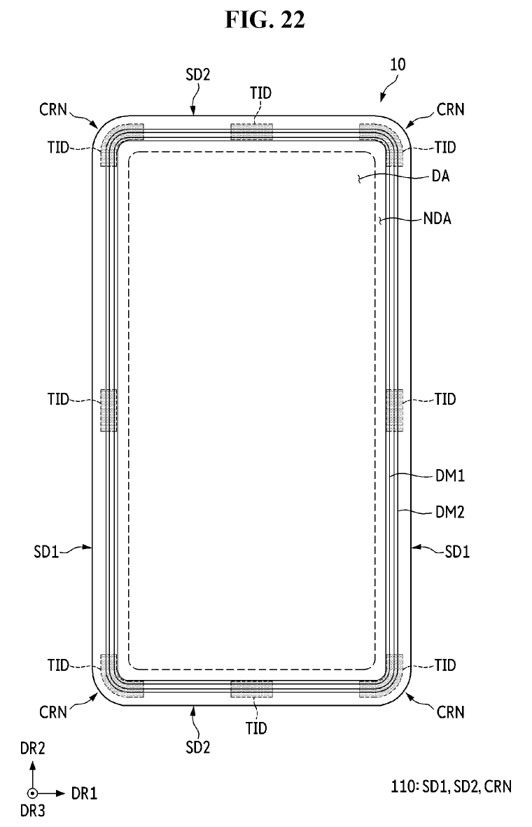

The display device 10 according to an embodiment of FIG. 22 is substantially the same as one embodiment illustrated in FIGS. 11 to 18, except that at least one inspection mark TID is located adjacent to a portion of each of the second sides SD2 and at least a portion of each of the corners CRN as well as a portion of each of the first sides SD1 in the edge of the substrate 110, such that the redundant description will be omitted below.

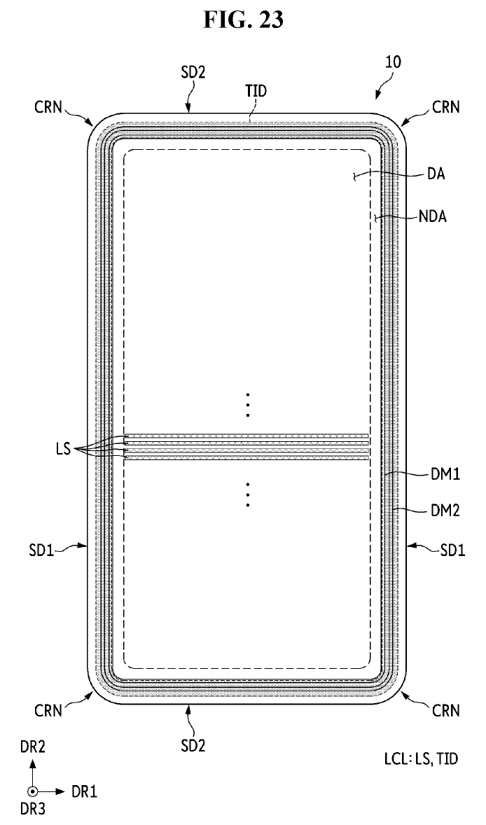

The display device 10 according to an embodiment of FIG. 23 is substantially the same as one embodiment illustrated in FIGS. 11 to 18, except that the inspection mark TID is located in a frame shape surrounding the periphery of the display area DA, such that the redundant description thereof will be omitted below.

In this way, the diffusion range of the main insulating layers MNI may be adjusted by the inspection mark TID as well as the smoothing area SLDA, thereby improving the quality reliability and defect rate of the display device 10.

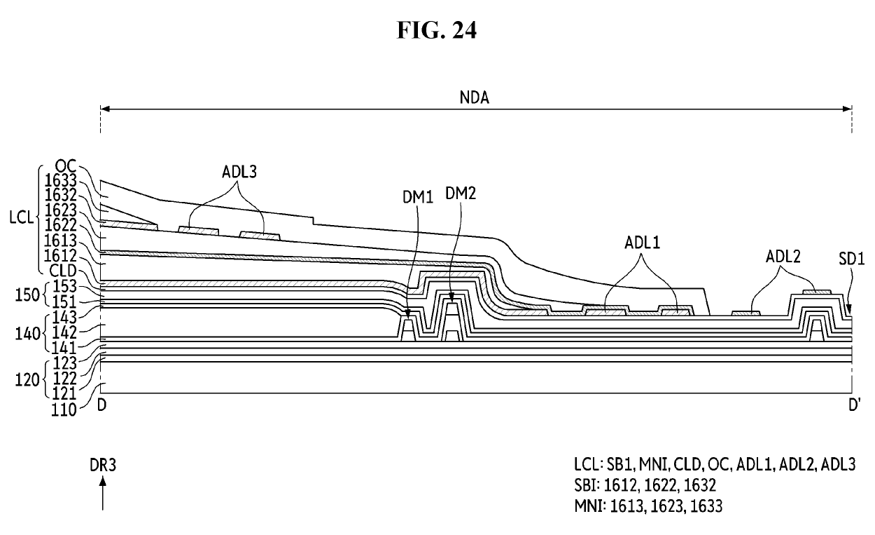

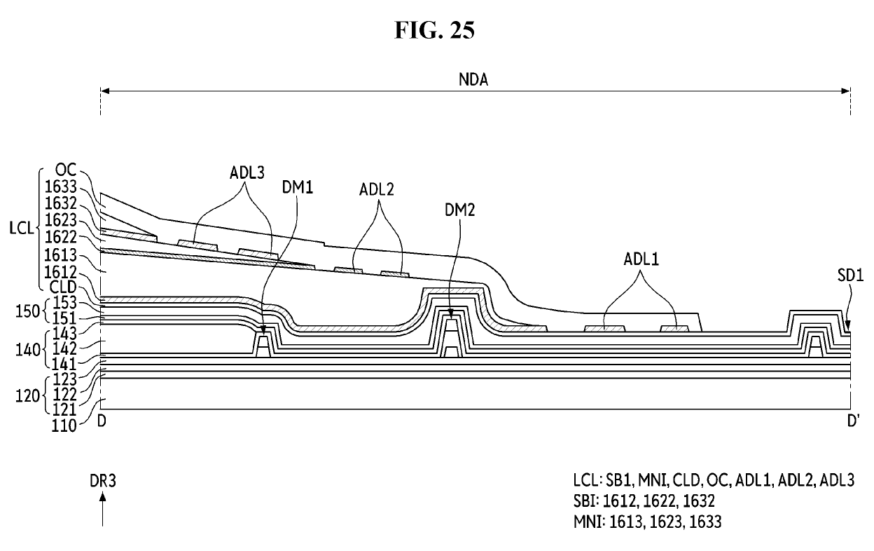

FIGS. 24 and 25 are cross-sectional views taken along line D-D' of FIG. 11 according to an embodiment.

The display device 10 according to an embodiment of FIG. 24 is substantially the same as one embodiment illustrated in FIGS. 11 to 18, except that the third sub-insulating layer 1632 and one or more third auxiliary dam layers ADL3 are located on the second main insulating layer 1623, such that the redundant description will be omitted below.

According to one embodiment of FIG. 24, the third sub-insulating layer 1632 does not cover at least one of one or more second auxiliary dam layers ADL2 and the second main insulating layer 1623, and one or more third auxiliary dam layers ADL3 spaced apart from the third sub-insulating layer 1632 are not located on the encapsulation layer 140. Since the third sub-insulating layer 1632 and one or more third auxiliary dam layers ADL3 are not located on the encapsulation layer 140 while being deviated from the second main insulating layer 1623, such that the width of the non-display area NDA may be reduced.

The display device 10 according to an embodiment of FIG. 25 is substantially the same as one embodiment illustrated in FIGS. 11 to 18, except that the second sub-insulating layer 1622 and one or more second auxiliary dam layers ADL2 are located on the first main insulating layer 1613, such that the redundant description will be omitted below.

According to one embodiment of FIG. 25, the second sub-insulating layer 1622 does not cover at least one of one or more first auxiliary dam layers ADL1 and the first main insulating layer 1613, and one or more second auxiliary dam layers ADL2 spaced apart from the second sub-insulating layer 1622 are not located on the encapsulation layer 140. Therefore, the second sub-insulating layer 1622 and one or more second auxiliary dam layers ADL2 are not located on the encapsulation layer 140 while being deviated from the first main insulating layer 1613, such that the width of the non-display area NDA may be reduced.

FIG. 26 is a cross-sectional view taken along line C-C' of FIG. 6 according to one embodiment.

The display device 10 according to one embodiment illustrated in FIG. 26 is substantially the same as or similar to the display device 10 according to one embodiment shown in FIG. 9, except that the first light output control layer 161 in the light path control layer LCL is located on the first cladding layer CLD1, a third light output control layer 163' in the light path control layer LCL does not include the third sub-insulating layer 1632 (see FIG. 9) but includes a second cladding layer CLD2 covering the third light blocking portions 1631 and a lens layer LNL located between the second cladding layer CLD2 and the third main insulating layer 1633, and the overcoat layer OC (see FIG. 9) covering the light output control layers 160 is not included. Therefore, redundant descriptions are omitted below.

As illustrated in FIG. 26, according to one embodiment, the lens layer LNL may be located on the second cladding layer CLD2 and may include lenses overlapping the transmission areas OA (see FIG. 6).

The lenses of the lens layer LNL may overlap the edges of the third light blocking portions 1631 in the third direction DR3.

Each lens of the lens layer LNL may have a convex lens-shaped cross-section protruding convexly relative to the substrate 110.

In this way, since the display device 10 according to one embodiment includes the lens layer LNL overlapping the transmission areas OA, light loss due to total reflection may be reduced. As a result, the light output efficiency and luminance of the display device 10 may be improved, thereby enhancing the display quality of the display device 10.

The second cladding layer CLD2 may be located on the second light output control layer 162 and may cover the third light blocking portions 1631.

The second cladding layer CLD2 may include an inorganic insulating material.

In this manner, the third light blocking portions 1631, the first light output control layer 161, and the second light output control layer 162 may be protected by the second cladding layer CLD2, thereby preventing and/or reducing damage to the organic materials included in the third light blocking portions 1631, the first light output control layer 161, and the second light output control layer 162 during the process of arranging the lens layer LNL.

The third main insulating layer 1633 may be located on the second cladding layer CLD2 and may cover the lens layer LNL.

According to one embodiment, the sub-insulating layers SBI (i.e., the first sub-insulating layer 1612 and the second sub-insulating layer 1622) may be located through a process of partially etching an organic insulating material deposited by a vapor deposition method, and may include an organic insulating material.

For example, the sub-insulating layers SBI may include at least one organic insulating material selected from the group consisting of propylene glycol methyl ether acetate, methacrylic acid-benzylmethacrylic acid copolymer, multi-functional acrylate, and a photo initiator.

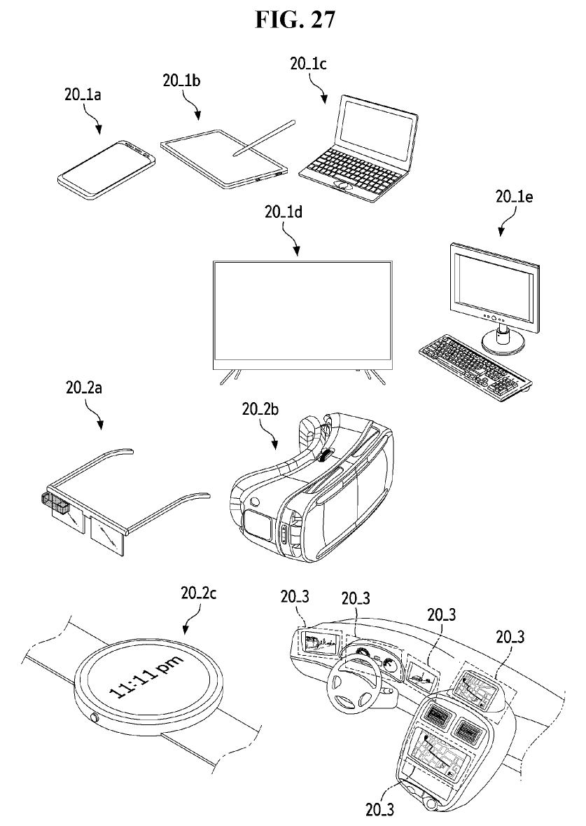

FIG. 27 is a cross-sectional view taken along line D-D' of FIG. 11 according to one embodiment.

FIG. 27 illustrates an example of a cross-section taken along line D–D' of FIG. 11 in the display device 10 according to one embodiment shown in FIG. 26.

The display device 10 according to one embodiment illustrated in FIG. 27 is substantially the same as or similar to the display device 10 according to one embodiment shown in FIG. 12, except that it includes a first additional dam portion ADD1 and a second additional dam portion ADD2 instead of the first dam portion DM1 (see FIG. 11) and the second dam portion DM2 (see FIG. 11); the light path control layer LCL further includes non-display light blocking portions (i.e., including a first non-display light blocking portion 1611', a second non-display light blocking portion 1621', and a third non-display light blocking portion 1631') that overlap the non-display area NDA and are located in the same layer as the light blocking portions LS (see FIG. 9), a first diffusion barrier layer DBL1 adjacent to the smoothing area SLDA and located in the same layer as the first non-display light blocking portion 1611', and a second diffusion barrier layer DBL2 adjacent to the first diffusion barrier layer DBL1 and located in the same layer as the second non-display light blocking portion 1621'; and at least one first auxiliary dam layer ADL1 and one or more second auxiliary dam layers ADL2 are located between the second diffusion barrier layer DBL2 and the edge of the substrate 110 (the first side SD1 in FIG. 11). Therefore, redundant descriptions are omitted below.

According to one embodiment, the first additional dam portion ADD1 and the second additional dam portion ADD2 may be located in the non-display area NDA in a ring shape sequentially surrounding the periphery of the display area DA (see FIG. 11).

The first additional dam portion ADD1 and the second additional dam portion ADD2 may be located on the first encapsulation layer 141 and may be covered by the third encapsulation layer 143.

The first additional dam portion ADD1 and the second additional dam portion ADD2 may be spaced apart from each other with the valley area VLA interposed between the first additional dam portion ADD1 and the second additional dam portion ADD2.

The first cladding layer CLD1 may overlap the entire substrate 110 and may cover the encapsulation layer 140.

According to one embodiment, the first non-display light blocking portion 1611' extending to the non-display area NDA may be located in the first cladding layer CLD1 and may overlap the first additional dam portion ADD1, the valley area VLA, the second additional dam portion ADD2, and the smoothing area SLDA.

According to one embodiment, a width W1 of the smoothing area SLDA may be greater than a width W2 of the valley area VLA.

For example, the width W1 of the smoothing area SLDA may be about 80 μm or more.

The diffusion of the organic insulating material for forming the first main insulating layer 1613 may be primarily slowed down in the valley area VLA and then further slowed down by the flat surface of the smoothing area SLDA, so that the first main insulating layer 1613 can diffuse up to the smoothing area SLDA.

According to one embodiment, the first sub-insulating layer 1612 may overlap the first additional dam portion ADD1 and may be spaced apart from the second additional dam portion ADD2.

In the smoothing area SLDA, the first main insulating layer 1613 may be in contact with the first non-display light blocking portion 1611'.

The first diffusion barrier layer DBL1 may be formed in the same layer as the first non-display light blocking portion 1611'.

The display device 10 according to one embodiment may include one or more first diffusion barrier layers DBL1 arranged between the smoothing area SLDA and the edge of the substrate 110 (i.e., the first side SD1 in FIG. 11).

According to one embodiment, a width W5 of one first diffusion barrier layer DBL1 adjacent to the smoothing area SLDA among the one or more first diffusion barrier layers DBL1 may be smaller than a width W6 between one first diffusion barrier layer DBL1 and the smoothing area SLDA.

According to one embodiment, the second non-display light blocking portion 1621' extending to the non-display area NDA may cover one first diffusion barrier layer DBL1 adjacent to the smoothing area SLDA among the one or more first diffusion barrier layers DBL1.

According to one embodiment, the second sub-insulating layer 1622 may overlap the first additional dam portion ADD1 and may be spaced apart from the second additional dam portion ADD2.

The diffusion of the organic insulating material for forming the second main insulating layer 1623 may be gradually slowed down in the valley area VLA and the smoothing area SLDA, and may be further slowed down by the valley formed between the first non-display light blocking portion 1611' and one or more first diffusion barrier layers DBL1.

Accordingly, between the smoothing area SLDA and the edge of the substrate 110 (i.e., the first side SD1 in FIG. 11), the second main insulating layer 1623 may come into contact with the second non-display light blocking portion 1621'.

According to one embodiment, the second diffusion barrier layer DBL2 may overlap another one of the one or more first diffusion barrier layers DBLb that is adjacent to the edge of the substrate 110 (i.e., the first side SD1 in FIG. 11).

According to one embodiment, the third non-display light blocking portion 1631' extending to the non-display area NDA may cover the second diffusion barrier layer DBL2.

According to one embodiment, the second cladding layer CLD2 may overlap the entire substrate 110 and cover the third non-display light blocking portion 1631'.

The diffusion of the organic insulating material for forming the third main insulating layer 1633 may be gradually slowed down in the valley area VLA and the smoothing area SLDA, and may be further slowed down by the valley formed between the second non-display light blocking portion 1621' and the second diffusion barrier layer DBL2.

Accordingly, between the smoothing area SLDA and the edge of the substrate 110 (i.e., the first side SD1 in FIG. 11), the third main insulating layer 1633 may be limitedly located within a range overlapping the third non-display light blocking portion 1631'. That is, the third main insulating layer 1633 may not extend beyond the third non-display light blocking portion 1631' to the edge of the substrate 110 (i.e., the first side SD1).

According to one embodiment, the first auxiliary dam layer ADL1 may be located in the same layer as the first sub-insulating layer 1612 and may extend to the edge of the substrate 110 (i.e., the first side SD1 in FIG. 11).

The first auxiliary dam layer ADL1 may cover the edge of another one of the one or more first diffusion barrier layers DBL1 that is adjacent to the edge of the substrate 110 (i.e., the first side SD1 in FIG. 11).

One or more second auxiliary dam layers ADL2 may be located on the first auxiliary dam layer ADL1 and may be formed in the same layer as the second sub-insulating layer 1622.

According to one embodiment, since the sub-insulating layers SBI (see FIG. 9, i.e., including the first sub-insulating layer 1612 and the second sub-insulating layer 1622) extend to the first additional dam portion ADD1, and the first auxiliary dam layer ADL1 and the one or more second auxiliary dam layers ADL2 are located adjacent to the edge of the substrate 110 (i.e., the first side SD1 in FIG. 11), it may be difficult to arrange at least one inspection mark TID (see FIG. 11).

Accordingly, in the display device 10 according to one embodiment, at least one inspection mark TID (see FIG. 11) is substantially the same as or similar to those of the embodiments illustrated in FIGS. 13 to 24, except that it is formed on the non-display light blocking portions (i.e., including the first non-display light blocking portion 1611', the second non-display light blocking portion 1621', and the third non-display light blocking portion 1631'), one or more first diffusion barrier layers DBL1, and the second diffusion barrier layer DBL2, instead of on the sub-insulating layers SBI (see FIG. 9, i.e., including the first sub-insulating layer 1612 and the second sub-insulating layer 1622), the first auxiliary dam layer ADL1, and the one or more second auxiliary dam layers ADL2. Therefore, redundant descriptions will be omitted below.

That is, according to one embodiment, the first mark group MG1 (see FIGS. 13, 14, and 15) may be formed on the first non-display light blocking portion 1611', the second mark group MG2 (see FIGS. 14 and 15) may be formed on the second non-display light blocking portion 1621', and the third mark group MG3 (see FIG. 15) may be formed on the third non-display light blocking portion 1631'.

One or more first auxiliary marks ADM1 (see FIGS. 13, 14, 15, and 16) may be formed on one or more first diffusion barrier layers DBL1.

The second auxiliary mark ADM2 (see FIGS. 14 and 15) may be formed on the second diffusion barrier layer DBL2.

The display device 10 of each embodiment as described herein may be applied to various electronic devices 20 (see FIG. 28).

The electronic device 20 (see FIG. 28) according to an embodiment may include the above-described display device 10.

In some aspects, the electronic device 20 (see FIG. 28) according to an embodiment may further include a module or device having other additional functions in addition to the display device 10.

FIG. 28 is a block diagram of an electronic device according to an embodiment.

Referring to FIG. 28, the electronic device 20 according to an embodiment may include a display module 21, a processor 22, a memory 23, and a power module 24.

The display module 21 may include the display device 10 that displays an image.

The processor 22 may include at least one of a central processing unit (CPU), an application processor (AP), a graphic processing unit (GPU), a communication processor (CP), an image signal processor (ISP), or a controller.

The memory 23 may store data information supportive of the operation of the processor 22 or the display module 21. In an example in which the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power for the operation of the electronic device 20.

At least one of the components of the electronic device 20 described herein may be included in the display device according to the embodiments described herein. Further, some of individual modules functionally included in one module may be included in the display device and some others may be provided separately from the display device. For example, the display device 10 may include the display module 21, and the processor 22, the memory 23, and the power module 24 may be provided in the form of other devices in the electronic device 20 other than the display device 10.

FIG. 29 is schematic views of electronic devices according to various embodiments.

Referring to FIG. 29, the electronic devices 20 according to the embodiments may include not only an image display electronic device such as a smartphone 20_1a, a tablet PC 20_1b, a laptop 20_1c, a TV 20_1d, and a desk monitor 20_1e, but also a wearable electronic device such as smart glasses 20_2a, a head mounted display 20_2b, and a smart watch 20_2c, and a vehicle electronic device 20_3 such as an instrument panel of a vehicle, a center fascia, a center information display (CID) of a dashboard, and a room mirror display.

In an embodiment, the electronic device 20 may be a center information display (CID) of a dashboard.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising a display area in which emission areas are arranged and a non-display area located around the display area;
an element layer comprising light emitting elements arranged in the emission areas on the substrate;
an encapsulation layer covering the element layer;
a light path control layer located on the encapsulation layer;
a first dam portion located in the non-display area and surrounding a periphery of the display area; and
a second dam portion located in the non-display area and surrounding a periphery of the first dam portion,
wherein the non-display area comprises:
a valley area located between the first dam portion and the second dam portion; and
a smoothing area located around the second dam portion,
wherein a width of the smoothing area is greater than a width of the valley area.

2. The display device of claim 1, wherein the light path control layer comprises:
two or more light output control layers overlapping the display area in a thickness direction of the substrate; and
at least one inspection mark located in the non-display area and adjacent to at least a portion of an edge of the substrate,
wherein each of the two or more light output control layers comprises:
light blocking portions overlapping the display area and spaced apart from each other;
a sub-insulating layer covering the light blocking portions; and
a main insulating layer located on the sub-insulating layer and including an organic insulating material,
wherein:
the at least one inspection mark comprises two or more mark groups spaced apart from each other, and
each of the two or more mark groups comprises:
at least one valley mark located in the valley area; and
one or more main marks located in the smoothing area,
wherein each of the at least one valley mark and the one or more main marks comprises engraved portions spaced apart from each other, and
each of the engraved portions is formed concavely in the sub-insulating layer of each of the two or more light output control layers.

3. The display device of claim 2, wherein each of the two or more light output control layers further comprises a sub-insulating layer located between the light blocking portions and the main insulating layer,
each of the sub-insulating layer and the main insulating layer extends to the non-display area, and
the two or more mark groups are located in the sub-insulating layers of the two or more light output control layers.

4. The display device of claim 2, wherein the light path control layer further comprises non-display light blocking portions overlapping the non-display area and located in the same layer as the light blocking portions of each of the two or more light output control layers, and
the main insulating layers of the two or more light output control layers and the non-display light blocking portions extend to the non-display area.

5. The display device of claim 2, wherein:
the edge of the substrate comprises two first sides facing each other in a first direction, two second sides facing each other in a second direction, and corners where one of the two first sides and one of the two second sides meet, and
one of the at least one inspection mark is located adjacent to a portion of one of the two first sides or a portion of one of the two second sides.

6. The display device of claim 2, wherein:
the edge of the substrate comprises two first sides facing each other in a first direction, two second sides facing each other in a second direction, and corners where one of the two first sides and one of the two second sides meet, and
one of the at least one inspection mark is located adjacent to at least a portion of one of the corners.

7. The display device of claim 2, wherein the at least one inspection mark is located in a frame shape surrounding the periphery of the display area.

8. The display device of claim 1, wherein:
the light path control layer comprises two or more light output control layers overlapping the display area in a thickness direction of the substrate, and
the two or more light output control layers comprise:
a first light output control layer located on the encapsulation layer;
a second light output control layer located on the first light output control layer; and
a third light output control layer located on the second light output control layer,
wherein:
the first light output control layer comprises:
first light blocking portions overlapping the display area and spaced apart from each other;
a first sub-insulating layer covering the first light blocking portions of the display area; and
a first main insulating layer located on the first sub-insulating layer,
the second light output control layer comprises:
second light blocking portions respectively overlapping the first light blocking portions and spaced apart from each other;
a second sub-insulating layer covering the second light blocking portions; and
a second main insulating layer located on the second sub-insulating layer, and
the third light output control layer comprises:
third light blocking portions respectively overlapping the first light blocking portions and the second light blocking portions and spaced apart from each other;
a third sub-insulating layer covering the third light blocking portions; and
a third main insulating layer located on the third sub-insulating layer,
wherein:
the first sub-insulating layer covers the first dam portion and the second dam portion of the non-display area and extends to the smoothing area, and
in the smoothing area, a thickness of the first main insulating layer is gradually reduced toward an edge of the substrate.

9. The display device of claim 8, wherein:
the light path control layer further comprises at least one inspection mark located in the non-display area and adjacent to at least a portion of the edge of the substrate,
the at least one inspection mark comprises:
a first mark group located in the first sub-insulating layer;
a second mark group located in the second sub-insulating layer; and
a third mark group located in the third sub-insulating layer,
wherein:
in a direction parallel to a portion of the edge of the substrate, the first mark group, the second mark group, and the third mark group are spaced apart from each other,
the first mark group comprises at least one first valley mark located in the valley area, and one or more first main marks located in the smoothing area,
the second mark group comprises at least one second valley mark located in the valley area, and one or more second main marks located in the smoothing area,
the third mark group comprises at least one third valley mark located in the valley area, and one or more third main marks located in the smoothing area,
the engraved portions of each of the at least one first valley mark and the one or more first main marks are formed concavely in the first sub-insulating layer,
the engraved portions of each of the at least one second valley mark and the one or more second main marks are formed concavely in the second sub-insulating layer, and
the engraved portions of each of the at least one third valley mark and the one or more third main marks are formed concavely in the third sub-insulating layer.

10. The display device of claim 9, wherein:
the light path control layer further comprises:
one or more first auxiliary dam layers arranged between the first sub-insulating layer and the edge of the substrate and located in the same layer as the first sub-insulating layer;
one or more second auxiliary dam layers arranged between the second sub-insulating layer and the edge of the substrate and located in the same layer as the second sub-insulating layer; and
one or more third auxiliary dam layers arranged in the same layer as the third sub-insulating layer and the second sub-insulating layer and located in the same layer as the third sub-insulating layer, and
the at least one inspection mark further comprises:
one or more first auxiliary marks located in the one or more first auxiliary dam layers;
one or more second auxiliary marks located in the one or more second auxiliary dam layers; and
one or more third auxiliary marks located in the one or more third auxiliary dam layers,
wherein:
the one or more first auxiliary marks, the one or more second auxiliary marks and the one or more third auxiliary marks are spaced apart from each other, and
each of the one or more first auxiliary marks, the one or more second auxiliary marks and the one or more third auxiliary marks comprises the engraved portions spaced apart from each other.

11. The display device of claim 8, wherein the light path control layer further comprises:
one or more first auxiliary dam layers arranged between the first sub-insulating layer and the edge of the substrate and located in the same layer as the first sub-insulating layer;
one or more second auxiliary dam layers arranged between the second sub-insulating layer and the edge of the substrate and located in the same layer as the second sub-insulating layer; and
one or more third auxiliary dam layers arranged in the same layer as the third sub-insulating layer and the second sub-insulating layer and located in the same layer as the third sub-insulating layer,
wherein the one or more first auxiliary dam layers are located on the encapsulation layer.

12. The display device of claim 11, wherein:
the second sub-insulating layer covers at least one of the one or more first auxiliary dam layers,
the one or more second auxiliary dam layers are located on the encapsulation layer, and
the third sub-insulating layer and the one or more third auxiliary dam layers are located on the second main insulating layer.

13. The display device of claim 11, wherein:
the second sub-insulating layer and the one or more second auxiliary dam layers are located on the first main insulating layer, and
the third sub-insulating layer and the one or more third auxiliary dam layers are located on the second main insulating layer.

14. The display device of claim 1, wherein the light path control layer comprises:
a first cladding layer located on the encapsulation layer;
a first light output control layer located on the first cladding layer;
a second light output control layer located on the first light output control layer; and
a third light output control layer located on the second light output control layer,
the first light output control layer comprises:
first light blocking portions overlapping the display area and spaced apart from each other;
a first sub-insulating layer covering the first light blocking portions of the display area; and
a first main insulating layer located on the first sub-insulating layer,
the second light output control layer comprises:
second light blocking portions respectively overlapping the first light blocking portions and spaced apart from each other;
a second sub-insulating layer covering the second light blocking portions; and
a second main insulating layer located on the second sub-insulating layer, and
the third light output control layer comprises:
third light blocking portions respectively overlapping the first light blocking portions and the second light blocking portions and spaced apart from each other;
a second cladding layer covering the third light blocking portions;
a lens layer located on the second cladding layer; and
a third main insulating layer covering the lens layer.

15. The display device of claim 14, wherein the light path control layer further comprises:
a first non-display light blocking portion overlapping the non-display area and formed in the same layer as the first light blocking portions;
a second non-display light blocking portion overlapping the non-display area and formed in the same layer as the second light blocking portions; and
a third non-display light blocking portion overlapping the non-display area and formed in the same layer as the third light blocking portions,
the first main insulating layer extends to the non-display area and is in contact with the first non-display light blocking portion in the smoothing area,
the second main insulating layer extends to the non-display area and is in contact with the second non-display light blocking portion in the smoothing area, and
the third main insulating layer extends to the non-display area and overlaps the third non-display light blocking portion.

16. An electronic device comprising:
a display device displaying an image;
a memory storing an application;
a processor executing the application and transmitting an image data signal and an input control signal to the display device; and
a power module transmitting power to the display device,
wherein the display device comprises:
a substrate comprising a display area in which emission areas are arranged and a non-display area located around the display area;
an element layer comprising light emitting elements arranged in the emission areas on the substrate;
an encapsulation layer covering the element layer;
a light path control layer located on the encapsulation layer;
a first dam portion located in the non-display area and surrounding a periphery of the display area; and
a second dam portion located in the non-display area and surrounding a periphery of the first dam portion,
wherein:
the light path control layer comprises two or more light output control layers overlapping the display area in a thickness direction of the substrate, and
the non-display area comprises:
a valley area located between the first dam portion and the second dam portion; and
a smoothing area located around the second dam portion,
wherein a width of the smoothing area is greater than a width of the valley area.

17. The electronic device of claim 16, wherein the two or more light output control layers comprise:
a first light output control layer located on the encapsulation layer;
a second light output control layer located on the first light output control layer; and
a third light output control layer located on the second light output control layer,
wherein:
the first light output control layer comprises:
first light blocking portions overlapping the display area and spaced apart from each other;
a first sub-insulating layer covering the first light blocking portions of the display area; and
a first main insulating layer located on the first sub-insulating layer,
the second light output control layer comprises:
second light blocking portions overlapping the first light blocking portions;
a second sub-insulating layer covering the second light blocking portions; and
a second main insulating layer located on the second sub-insulating layer, and
the third light output control layer comprises:
third light blocking portions overlapping the first light blocking portions and the second light blocking portions;
a third sub-insulating layer covering the third light blocking portions; and
a third main insulating layer located on the third sub-insulating layer,
wherein:
the first sub-insulating layer covers the first dam portion and the second dam portion of the non-display area and extends to the smoothing area, and
in the smoothing area, a thickness of the first main insulating layer is gradually reduced toward an edge of the substrate.

18. The electronic device of claim 17, wherein the light path control layer further comprises at least one inspection mark located in the non-display area and adjacent to at least a portion of the edge of the substrate, and
the at least one inspection mark comprises:
a first mark group located in the first sub-insulating layer;
a second mark group located in the second sub-insulating layer; and
a third mark group located in the third sub-insulating layer,
wherein:
in a direction parallel to a portion of the edge of the substrate, the first mark group, the second mark group, and the third mark group are spaced apart from each other,
the first mark group comprises at least one first valley mark located in the valley area between the first dam portion and the second dam portion, and one or more first main marks located in the smoothing area,
the second mark group comprises at least one second valley mark located in the valley area, and one or more second main marks located in the smoothing area,
the third mark group comprises at least one third valley mark located in the valley area, and one or more third main marks located in the smoothing area,
engraved portions of each of the at least one first valley mark and the one or more first main marks are formed concavely in the first sub-insulating layer,
engraved portions of each of the at least one second valley mark and the one or more second main marks are formed concavely in the second sub-insulating layer, and
engraved portions of each of the at least one third valley mark and the one or more third main marks are formed concavely in the third sub-insulating layer.

19. The electronic device of claim 16, wherein the light path control layer comprises:
a first cladding layer located on the encapsulation layer;
a first light output control layer located on the first cladding layer;
a second light output control layer located on the first light output control layer; and
a third light output control layer located on the second light output control layer,
the first light output control layer comprises:
first light blocking portions overlapping the display area and spaced apart from each other;
a first sub-insulating layer covering the first light blocking portions of the display area; and
a first main insulating layer located on the first sub-insulating layer,
the second light output control layer comprises:
second light blocking portions respectively overlapping the first light blocking portions and spaced apart from each other;
a second sub-insulating layer covering the second light blocking portions; and
a second main insulating layer located on the second sub-insulating layer, and
the third light output control layer comprises:
third light blocking portions respectively overlapping the first light blocking portions and the second light blocking portions and spaced apart from each other;
a second cladding layer covering the third light blocking portions;
a lens layer located on the second cladding layer; and
a third main insulating layer covering the lens layer.

20. The electronic device of claim 19, wherein the light path control layer further comprises:
a first non-display light blocking portion overlapping the non-display area and formed in the same layer as the first light blocking portions;
a second non-display light blocking portion overlapping the non-display area and formed in the same layer as the second light blocking portions; and
a third non-display light blocking portion overlapping the non-display area and formed in the same layer as the third light blocking portions,
the first main insulating layer extends to the non-display area and is in contact with the first non-display light blocking portion in the smoothing area,
the second main insulating layer extends to the non-display area and is in contact with the second non-display light blocking portion in the smoothing area, and
the third main insulating layer extends to the non-display area and overlaps the third non-display light blocking portion.
